(19) United States
(12) Patent Application Publication
(10) Pub. No.: US 2003/0042525 A1
(43) Pub. Date: Mar. 6, 2003

(54) Semiconductor apparatus having vertical structure

(76) Inventor: Masahiro Tanaka, Yokohama-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/230,119

(22) Filed: Aug. 29, 2002

(30) Foreign Application Priority Data
Aug. 29, 2001 (JP) 2001-260228

(51) Int. Cl. H01L 27/108

(52) U.S. Cl. 257/302

(57) ABSTRACT

This semiconductor apparatus includes a semiconductor element having a structure which becomes conductive by movement of the carrier in the vertical direction of a semiconductor substrate. Further, this semiconductor apparatus includes a joint substrate joined to the semiconductor substrate in order to give mechanical strength to the semiconductor element.

### CROSS-REFERENCE TO RELATED APPLICATIONS

This application is based upon and claims the benefit of priority from the prior Japanese Patent Application No. 2001-260228, filed Aug. 29, 2001, the entire contents of which are incorporated herein by reference.

### BACKGROUND OF THE INVENTION

1. Field of the Invention

The present invention relates to a semiconductor apparatus having a vertical structure. More particularly, the present invention relates to a vertical semiconductor apparatus including a semiconductor element having a structure which becomes conductive by movement of a carrier in the vertical direction of a semiconductor substrate.

2. Description of the Related Art

A conventional vertical semiconductor apparatus is constituted by using a single semiconductor substrate. FIG. 42 shows a structure of an IGBT (Insulated Gate Bipolar Transistor) which is one of the vertical semiconductor apparatuses. In case of this IGBT, for example, a plurality of p type base layers 102 are formed in a surface area of an n− type semiconductor substrate 101. A plurality of n+ emitter layers 103 are formed in a surface area of each p− type base layer 102. A plurality of emitter electrodes 104 are arranged on the surface of the n− type semiconductor substrate 101. Each emitter electrode 104 is connected to the p type base layer 102 and the n+ emitter layer 103, respectively. Further, a plurality of gate electrodes 106 are formed on the surface of the n− type semiconductor substrate 101 with each gate insulation film 105 interposed therebetween. Each gate electrode 106 is adjacent to the n− type semiconductor substrate 101, the p type base layer 102 and the n+emitter layer 103.

On the other hand, a p+ type collector layer 107 is formed in a lower (back side) area of the n− type semiconductor substrate 101, i.e., on the surface where the gate electrode 106 is not formed. Furthermore, a collector electrode 108 is formed on the lower surface of the p+ type collector layer 107.

In the prior art IGBT, a substrate thickness required as an apparatus mainly depends on a depletion layer thickness when an electric current is interrupted. That is, the substrate thickness mainly depends on a withstand voltage. Therefore, when the substrate thickness is reduced, the withstand voltage of the apparatus is lowered. Moreover, when the substrate thickness is reduced, mechanical strength is decreased. Thus, in the apparatus with the low withstand voltage, the mechanical strength is assured by forming the p+ type collector layer 107 thick.

In terms of the characteristic of the IGBT, it is not necessary to form the p+ type collector layer 107 thick. That is because the p+ type collector layer 107 provokes a parasitic operation or becomes a resistor. In addition, the n− type semiconductor substrate 101 is an epitaxial layer, which increases the cost.

However, in order to facilitate handling, for example, prevent warpage during manufacture or damages to a product, a substrate having a certain degree of thickness must be used.

As described above, in the prior art, the thickness of the substrate must be reduced in order to improve the performance. However, there is a problem that the mechanical strength is lowered when the thickness of the substrate is reduced.

### BRIEF SUMMARY OF THE INVENTION

A semiconductor apparatus according to a first aspect of the present invention comprises: a semiconductor element having a structure which becomes conductive by movement of a carrier in the vertical direction of a semiconductor substrate; and a joint substrate joined to the semiconductor substrate in order to give mechanical strength to the semiconductor element.

A semiconductor apparatus according to a second aspect of the present invention comprises: a first main electrode; a joint substrate formed on the first main electrode; a semiconductor layer formed on the joint substrate; a base layer formed in a main surface of the semiconductor layer; an impurity diffusion layer formed in the base layer; a second main electrode connected to the impurity diffusion layer and the base layer; and a gate electrode formed over a portion between the semiconductor layer and the diffusion layer via an insulation film.

A semiconductor apparatus according to a third aspect of the present invention comprises: a first main electrode; a semiconductor layer formed on the first main electrode; a base layer formed in a main surface of the semiconductor layer; an impurity diffusion layer formed in the base layer; a second main electrode connected to the impurity diffusion layer and the base layer; a gate electrode formed over a portion between the semiconductor layer and the diffusion layer via an insulation film; and a joint substrate joined to a lower surface of the first main electrode.

### BRIEF DESCRIPTION OF THE SEVERAL VIEWS OF THE DRAWING

FIG. 1 is a cross-sectional view showing an example in which a structure of a vertical semiconductor apparatus according to a first embodiment of the present invention is applied to a punch-through type IGBT having a planar gate structure;

FIG. 2 is a characteristic view showing a result of simulating a withstand voltage at the time of turn-off of the IGBT illustrated in FIG. 1 by comparing D5 having a thickness of 35 μm with the same having 55 μm;

FIG. 3 is a characteristic view showing a result of simulating an ON voltage of the IGBT illustrated in FIG. 1 by comparing D5 having a thickness of 70 μm with the same having 55 μm;

FIG. 4 is a characteristic view showing a result of simulating a loss at the time of turn-off of the IGBT illustrated in FIG. 1 by comparing D5 having a thickness of 70 μm with the same having 55 μm;

FIG. 5 is a characteristic view showing a result of simulating an ON voltage of the IGBT illustrated in FIG. 1 when D2 has a thickness of 3 μm in comparison with the same when D2 has a thickness of 10 μm;

FIG. 6 is a characteristic view showing a result of simulating an ON voltage of the IGBT illustrated in FIG. 1 when D3 has a thickness of 1 μm in comparison with the same when D3 has a thickness of 10 μm;

FIG. 7 is a characteristic view showing a result of simulating a loss at the time of turn-off of the IGBT illustrated in FIG. 1 when D4 has a thickness of 1 μm in comparison with the same when D4 has a thickness of 10 μm;

FIGS. 8A, 8B, 8C, and 8D are process sectional views for illustrating a method for manufacturing a vertical semiconductor apparatus having a structure illustrated in FIG. 1;

FIGS. 9A, 9B, 9C, and 9D are process sectional views for illustrating another method for manufacturing a vertical semiconductor apparatus having a structure illustrated in FIG. 1;

FIGS. 10A, 10B, 10C, 10D and 10E are process sectional views for illustrating still another method for manufacturing a vertical semiconductor apparatus having a structure illustrated in FIG. 1;

FIG. 11 is a cross-sectional view showing another structural example of the vertical semiconductor apparatus according to the first embodiment of the present invention;

FIGS. 12A and 12B are process sectional views for illustrating a method for manufacturing the vertical semiconductor apparatus having the structure illustrated in FIG. 11;

FIG. 13 is a cross-sectional view showing an example where a structure of a vertical semiconductor apparatus according to a second embodiment of the present invention is applied to the punch-through type IGBT having a trench gate structure;

FIG. 14 is a cross-sectional view showing another structural example of the vertical semiconductor apparatus according to the second embodiment of the present invention;

FIG. 15 is a cross-sectional view showing an example where a structure of a vertical semiconductor apparatus according to a third embodiment of the present invention is applied to a non-punch-through type IGBT having a planar gate structure;

FIG. 16 is a characteristic view showing a result of simulating a withstand voltage at the time of turn-off of the IGBT illustrated in FIG. 15 when D5 has a thickness of 75 μm in comparison with the same when D5 has a thickness of 95 μm;

FIG. 17 is a characteristic view showing a result of simulating an ON voltage of the IGBT illustrated in FIG. 15 when D5 has a thickness of 95 μm in comparison with the same when D5 has a thickness of 120 μm;

FIG. 18 is a characteristic view showing a result of simulating a loss at the time of turn-off of the IGBT illustrated in FIG. 15 when D5 has a thickness of 95 μm in comparison with the same when D5 has a thickness of 120 μm;

FIG. 19 is a characteristic view showing a result of simulating an ON voltage of the IGBT illustrated in FIG. 15 when D2 has a thickness of 3.1 μm in comparison with the same when D2 has a thickness of 10 μm;

FIG. 20 is a characteristic view showing a result of simulating a loss at the time of turn-off of the IGBT illustrated in FIG. 15 when D4 has a thickness of 1 μm in comparison with the same when D4 has a thickness of 10 μm;

FIGS. 21A, 21B, 21C and 21D are process sectional views for illustrating a method for manufacturing the vertical semiconductor apparatus having the structure illustrated in FIG. 15;

FIG. 22 is a cross-sectional view showing another structural example of the vertical semiconductor apparatus according to the third embodiment of the present invention;

FIG. 23 is a cross-sectional view showing an example where a structure of a vertical semiconductor apparatus according to a fourth embodiment of the present invention is applied to the non-punch-through type IGBT having the trench gate structure;

FIG. 24 is a cross-sectional view showing still another structural example of the vertical semiconductor apparatus according to the fourth embodiment of the present invention;

FIG. 25 is a cross-sectional view showing an example where a structure of a vertical semiconductor apparatus according to a fifth embodiment of the present invention is applied to a punch-through type MOSFET (Metal Oxide Semiconductor Field Effect Transistor) having a planar gate structure;

FIGS. 26A, 26B, 26C and 26D are process sectional views for illustrating a method for manufacturing the vertical semiconductor apparatus having the structure illustrated in FIG. 25;

FIG. 27 is a cross-sectional view showing another structural example of the vertical semiconductor apparatus according to the fifth embodiment of the present invention;

FIG. 28 is a cross-sectional view showing an example where a structure of a vertical semiconductor apparatus according to a sixth embodiment of the present invention is applied to the punch-through type MOSFET having the trench gate structure;

FIG. 29 is a cross-sectional view showing another structural example of the vertical semiconductor apparatus according to the sixth embodiment of the present invention;

FIG. 30 is a cross-sectional view showing an example where a structure of a vertical semiconductor apparatus according to a seventh embodiment of the present invention is applied to the non-punch-through type MOSFET having a planar gate structure;

FIGS. 31A, 31B, and 31C are process sectional views for illustrating a method for manufacturing the vertical semiconductor apparatus having the structure illustrated in FIG. 30;

FIG. 32 is a cross-sectional view showing another structural example of the vertical semiconductor apparatus according to the seventh embodiment of the present invention;

FIG. 33 is a cross-sectional view showing an example where a structure of a vertical semiconductor apparatus according to an eighth embodiment of the present invention is applied to the non-punch-through type MOSFET having the trench gate structure;

FIG. 34 is a cross-sectional view showing another structural example of the vertical semiconductor apparatus according to the eighth embodiment of the present invention;

FIGS. 35A, 35B, and 35C are process cross-sectional views for illustrating a method for manufacturing a vertical semiconductor apparatus according to a ninth embodiment of the present invention;

FIGS. 36A, 36B, and 36C are process sectional views for illustrating a method for manufacturing a vertical semiconductor apparatus according to a 10th embodiment of the present invention;

FIG. 37 is a cross-sectional view showing an example where a structure of a vertical semiconductor apparatus according to an 11th embodiment of the present invention is applied to a punch-through diode;

FIGS. 38A, 38B, 38C, and 38D are process sectional views for illustrating a method for manufacturing the vertical semiconductor apparatus having the structure illustrated in FIG. 37;

FIG. 39 is a cross-sectional view showing another structural example of the vertical semiconductor apparatus according to the 11th embodiment of the present invention;

FIG. 40 is a cross-sectional view showing an example where a structure of a vertical semiconductor apparatus according to a 12th embodiment of the present invention is applied to the non-punch-through type diode;

FIG. 41 is a cross-sectional view showing another structural example of the vertical semiconductor apparatus according to the 12th embodiment of the present invention; and

FIG. 42 is a cross-sectional view of the IGBT for illustrating a prior art and its problem.

### DETAILED DESCRIPTION OF THE INVENTION

(First Embodiment)

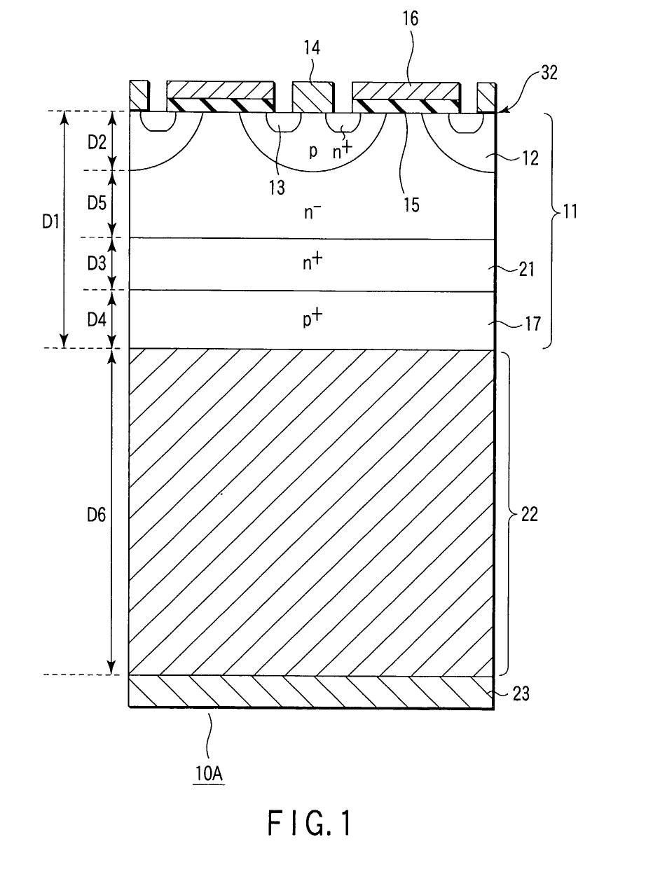

FIG. 1 shows a structural example of a vertical semiconductor apparatus 10A according to a first embodiment of the present invention. Incidentally, here, description will be given as to an example in which the embodiment of the present invention is applied to the IGBT having a planar gate structure. Further, this IGBT is of a punch-through type that a buffer layer is provided to a part of a substrate.

In FIG. 1, a plurality of p type base layers 12 which are of the second conductive type are formed in a surface area of an n− type semiconductor substrate (for example, monocrystal silicon) 11 which is of the first conductive type. A plurality of n+ type emitter layers 13 are formed in a surface area of each p type base layer 12. A plurality of emitter electrodes 14 are arranged on the surface of the n− type semiconductor substrate 11. Each emitter electrode 14 is connected to the p type base layer 12 and the n+ type emitter layer 13. Furthermore, a plurality of gate electrodes 16 are formed on the surface of the n− type semiconductor substrate 11 with each gate insulation film 15 interposed therebetween. Each gate electrode 16 is adjacent to the n− type semiconductor substrate 11, the p type base layer 12 and the n+ type emitter layer 13. In this manner, an MOS (Metal Oxide Semiconductor) structure 32 having a planar gate structure is formed on a surface portion of the n− type semiconductor substrate 11.

On the other hand, an n+ type buffer layer 21 and a p+ type collector layer (carrier injection layer) 17 are formed in a lower (back side) area of the n− type semiconductor substrate 11, i.e., on the surface where the MOS structure 32 is not formed. This consequently realizes a punch-through type IGBT (semiconductor element) having a so-called planer gate structure which becomes conductive in response to movement of the carrier in the vertical direction of the n− type semiconductor substrate 11.

Moreover, a joint substrate 22 is joined to the lower surface (back side) of the n− type semiconductor substrate 11. That is, this joint substrate 22 is provided to contact with the p+ type collector layer 17. The joint substrate 22 is formed by using a metal (conductive material) such as aluminium (Al). In addition, a substrate electrode (first electrode) 23 can be provided on the surface of the joint substrate 22 which is not joined to the n− type semiconductor substrate 11. However, the substrate electrode 23 is formed by using nickel (Ni) or gold (Au) which is superior to the joint substrate 22 in joint property with respect to solder when mounting the vertical semiconductor apparatus 10A, for example. That is, when the joint substrate 22 is formed by using a metal having the good joint property with respect to solder, the substrate electrode 23 does not have to be provided.

In case of this embodiment, the vertical semiconductor apparatus 10A is formed with a thickness of approximately 400 μm as a whole, for example.

In the vertical semiconductor apparatus 10A having such a structure, for example, assuming that the withstand voltage of the IGBT is 600 V, 1.5×10¹⁴ cm⁻³ is desirable as the density of the n− type semiconductor substrate 11. Additionally, approximately 1.0×10¹⁸ cm⁻³ is desirable as the maximum density of the n+ type buffer layer 21.

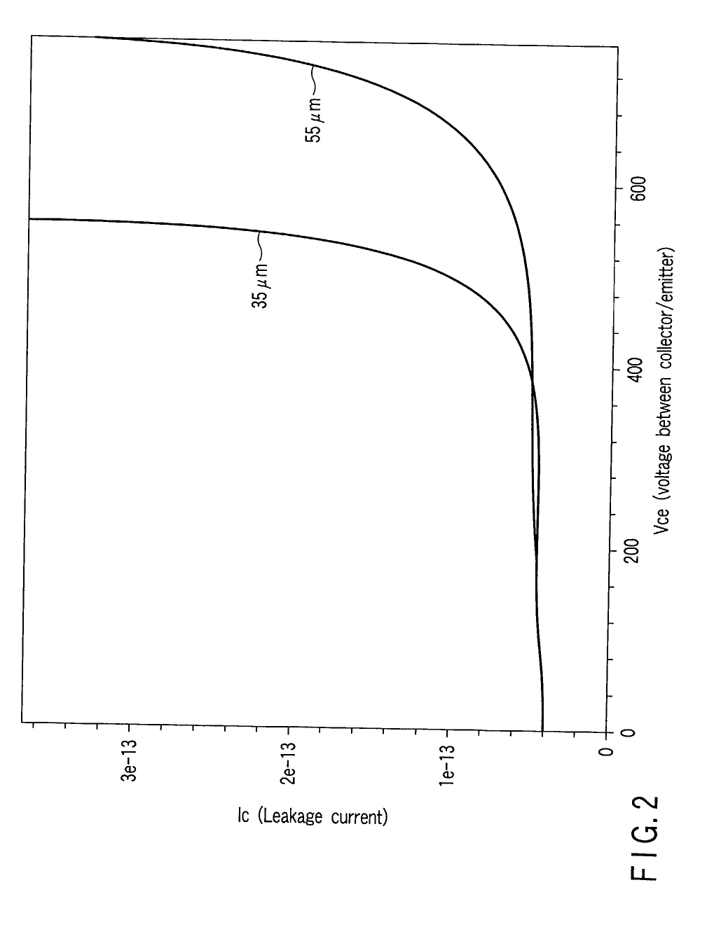

FIG. 2 shows a result of simulating the withstand voltage at the time of turn-off when it is assumed that the withstand voltage of the IGBT is 600 V. It is to be noted that description will be given as to the cases where a thickness of D5 in FIG. 1 is 35 μm and 55 μm. As apparent from FIG. 2, as a thickness D5 obtained by subtracting a thickness D2 of the p type base layer 12, a thickness D3 of the n+ type buffer layer 21 and a thickness D4 of the p+ type collector layer 17 from a thickness D1 of the n− type semiconductor substrate 11, a thickness of approximately 55 μm is desirable. When the thickness of D5 is set to a value smaller than 55 μm, e.g., 35 μm, the breakdown occurs with the voltage of not more than 600 V, which results in insufficient withstand voltage.

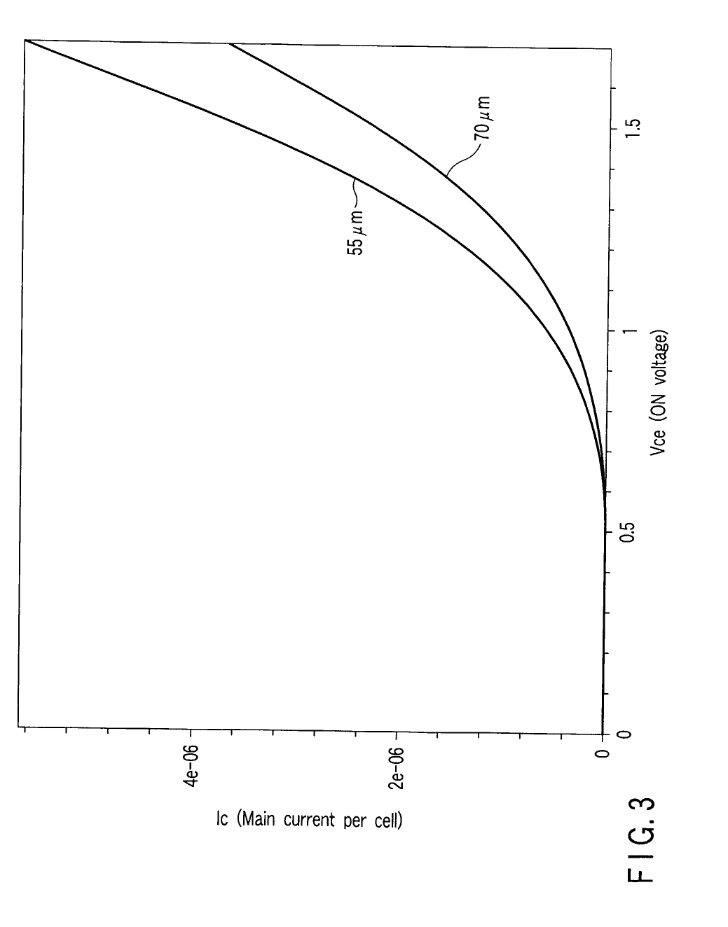

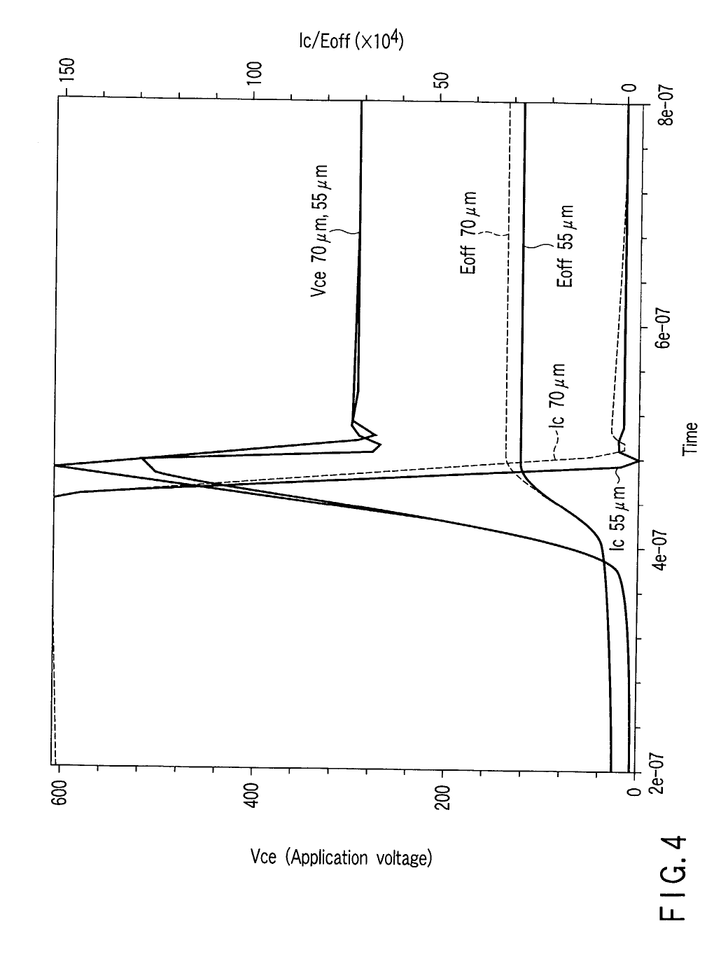

FIG. 3 shows a result of simulating an ON voltage of the IGBT, and FIG. 4 shows a result of simulating a loss (Eoff) at the time of turn-off. It is to be noted that description will be given as to cases where the thickness of D5 in FIG. 4 is 70 μm and 55 μm. When the thickness of D5 is set to a value larger than 55 μm, e.g., 70 μm, as apparent from FIG. 3, a saturation voltage between the emitter and the collector, namely, the ON voltage increases. Further, as apparent from FIG. 4, the loss at the time of turn-off increases.

In this manner, in the punch-through type IGBT, an optimum value of the thickness D5 exists in accordance with the necessary withstand voltage. Furthermore, an optimum value according to the withstand voltage exists with respect to each of the thickness D2 of the p type base layer 12, the thickness D3 of the n+ type buffer layer 21 and the thickness D4 of the p+ type collector layer 17.

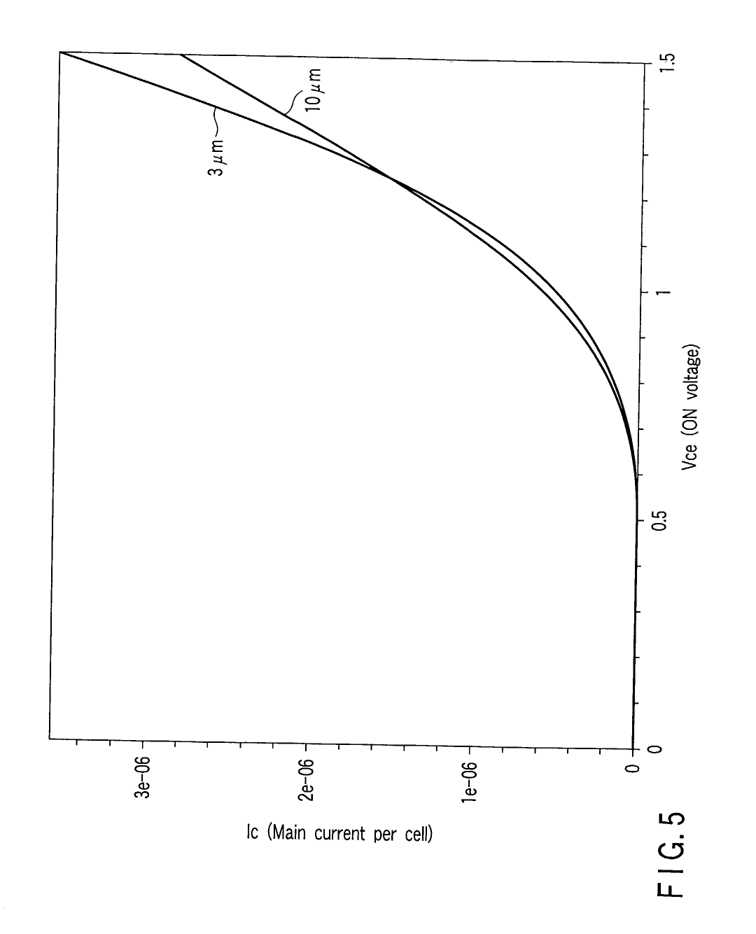

FIG. 5 shows a result of simulating an ON voltage of the IGBT. Incidentally, here, description will be given as to the cases where the thickness D2 of the p type base layer 12 is set to 3 μm and 10 μm. As apparent from FIG. 5, it is desirable to reduce the thickness D2 of the p type base layer 12 so as to be capable of maintaining the withstand voltage and, for example, approximately 3 μm is desirable. When the thickness D2 of the p type base layer 12 is large, e.g., 10 μm, the loss in the ON state increases.

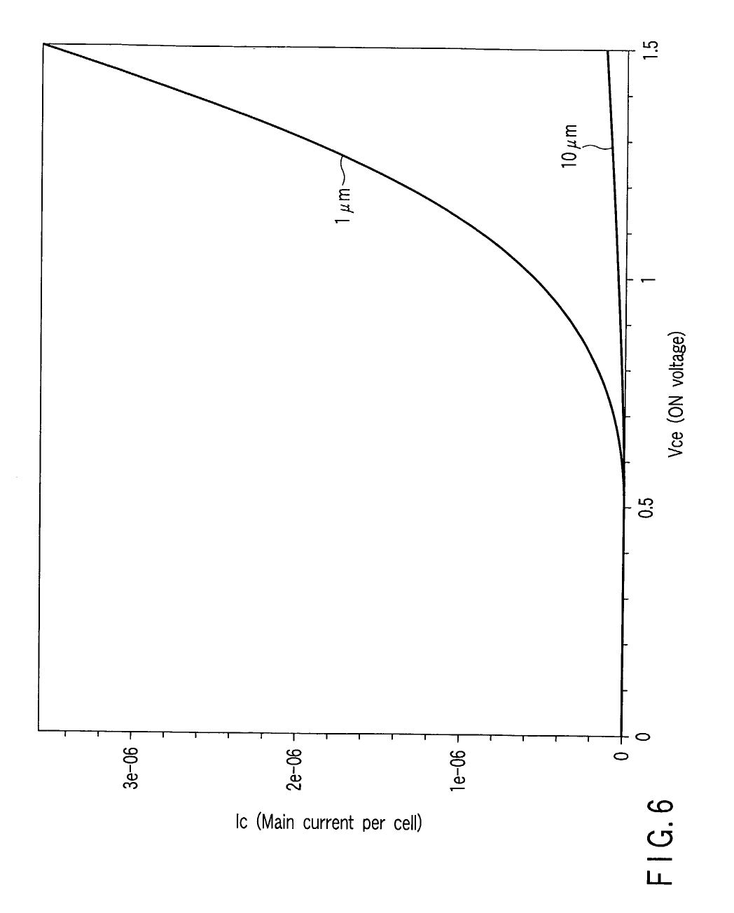

FIG. 6 shows a result of simulating an ON voltage of the IGBT. Incidentally, here, description will be given as to cases where the thickness D3 of the n+ type buffer layer 21 is set to 1 μm and 10 μm. As apparent from FIG. 6, it is desirable that the thickness D3 of the n+ type buffer layer 21 is reduced so as to be capable of maintaining the withstand voltage and, for example, approximately 1 μm is desirable. When the thickness D3 of the n+buffer layer 21 is large, e.g., 10 μm, the loss in the ON state increases.

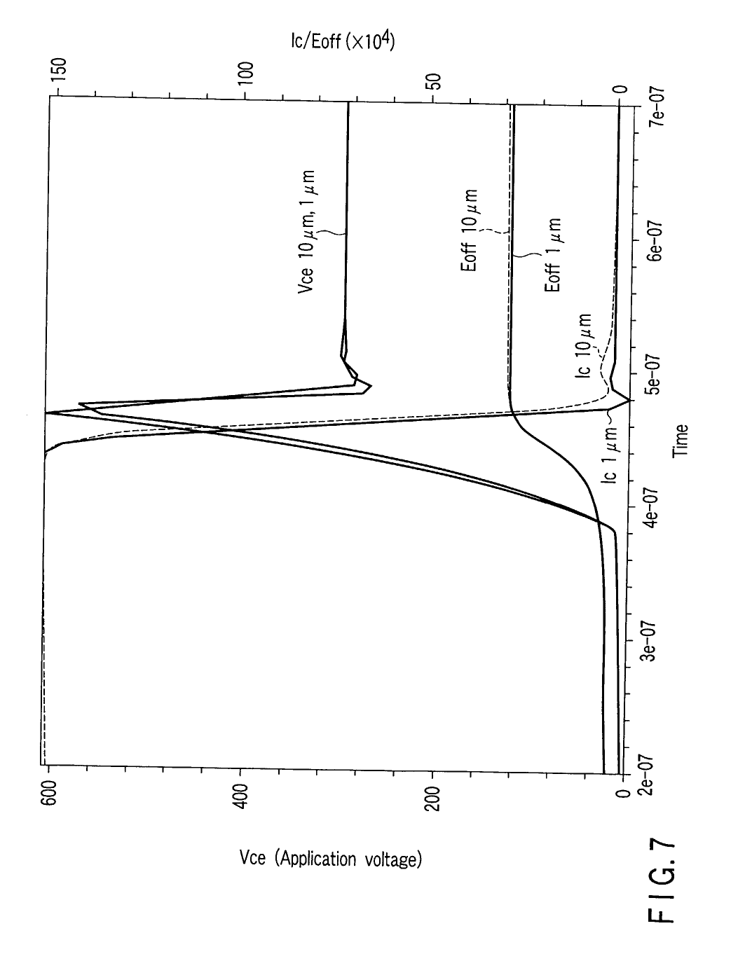

FIG. 7 shows a result of simulating the loss at the time of turn-off of the IGBT. Incidentally, here, cases where the thickness D4 of the p+ type collector layer 17 is 1 μm and where it is 10 μm are illustrated. As apparent from FIG. 7, it is preferable that the thickness D4 of the p+ type collector layer 17 is thin so as to allow injection of a sufficient amount of the carrier. For example, the thickness of approximately 1 μm (depth is not more than 10 μm) is desirable. When the thickness D4 of the p+ type collector layer 17 is set large, e.g., to 10 μm, the loss at the time of turn-off increases.

Based on this, in case of producing the punch-through type IGBT having the planar gate structure whose withstand voltage is 600 V, the thickness D1 of the n− type semiconductor substrate 11 is, e.g., 60 μm. As a result, it is possible to realize the IGBT with less loss irrespective of existence/absence of the joint substrate 22.

Here, in cases where a material of the n− type semiconductor substrate 11 is monocrystal silicon and the IGBT with the withstand voltage of 600 V is produced, as described above, when it is assumed that the thickness D1 of the n− type semiconductor substrate 11 is 60 μm, the IGBT with less loss can be realized. However, when the thickness D1 of the n− type semiconductor substrate 11 is not more than 100 μm, mechanical strength is insufficient. Therefore, it may be readily destroyed by an impact shock from the outside during or after manufacture. Therefore, the joint substrate 22 is joined to the IGBT, and the thickness D6 of the joint substrate 22 is set to, e.g., approximately 340 μm (not less than 200 μm). As a result, the cost can be reduced as compared with the case where the epitaxial layer is formed, the sufficient mechanical strength is obtained, and the high-performance IGBT with less loss can be provided.

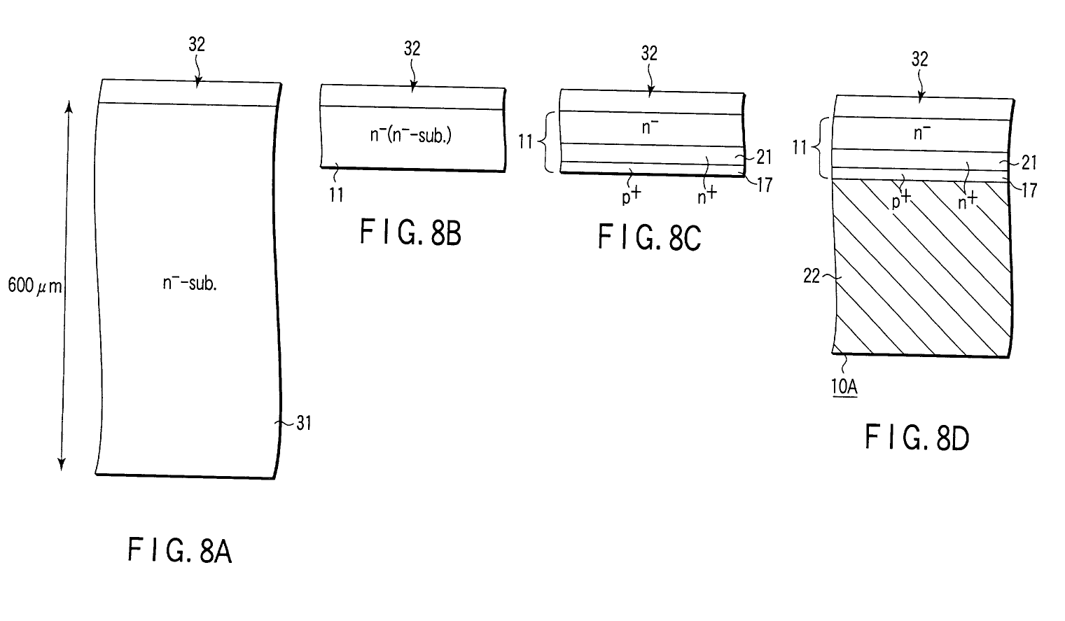

FIGS. 8A to 8D show a method of producing the vertical semiconductor apparatus 10A having the structure illustrated in FIG. 1. In case of producing the vertical semiconductor apparatus 10A, for example, an n− type wafer (first conductive type semiconductor substrate (n−-Sub.)) 31 having a thickness of approximately 600 μm is prepared as shown in FIG. 8A. Then, an MOS structure 32 having the planar gate structure is formed at the surface portion of the wafer 31. That is, a plurality of p type base layers 12 are first formed with the thickness of approximately 3 μm in a surface area of the n− type wafer 31 by diffusion of impurities. Thereafter, a gate insulation film 15 and a gate electrode 16 are formed on the surface of the n− type wafer 31. Further, an emitter electrode 14 is formed on the surface of the n− type wafer 31 before and after formation of the gate electrode 16. Then, with the gate electrode 16 and the emitter electrode 14 being used as masks, the n+ type emitter layer 13 is formed in a surface area of the p type base layer 12 by diffusion of impurities. In this manner, the MOS structure 32 having the planar gate structure is formed at the surface portion of the n− type wafer 31.

Subsequently, for example, as shown in FIG. 8B, a part of a surface of the n− type wafer 31 on which the MOS structure 32 is not formed is removed by a polishing method or the like. In this case, the thickness D1 of the n− type semiconductor substrate 11 excluding the gate electrode 16 and the emitter electrode 14 is set to approximately 60 μm.

Subsequently, for example, as shown in FIG. 8C, an n+ type buffer layer 21 and a p+ type collector layer 17 are respectively formed on the surface of the n− type semiconductor substrate 11 on which the MOS structure 32 is not formed. At this moment, the n+ type buffer layer 21 and the p+ type collector layer 17 are respectively formed with the thickness of approximately 1 μm by ion implantation method instead of the epitaxial growth method.

In this manner, after forming the IGBT, as shown in FIG. 8D for example, the joint substrate 22 having the thickness of 340 μm is brought into contact with the surface of the n− type semiconductor substrate 11 on which the MOS structure 32 is not formed. Then, the IGBT and the joint substrate 22 are joined to each other by, e.g., heating.

Further, the substrate electrode 23 is formed on the non-joining surface of the joint substrate 22 relative to the n− type semiconductor substrate 11 according to needs. Furthermore, the vertical semiconductor apparatus 10A having the structure shown in FIG. 1 is finally completed by performing separation/division in accordance with each IGBT.

In this embodiment, when manufacturing the vertical semiconductor apparatus 10A, a wafer having the thickness of 600 μm is used. Therefore, the sufficient mechanical strength can be assured not only after completion of the vertical semiconductor apparatus 10A but with respect to warpage or an impact shock from the outside during manufacture.

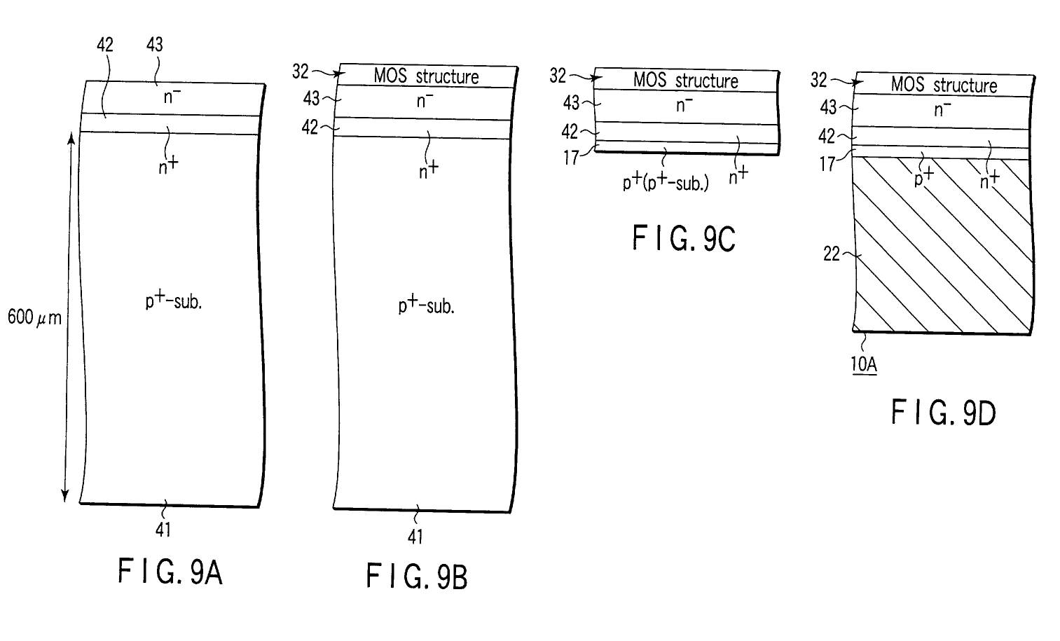

FIGS. 9A to 9D show another method of manufacturing the vertical semiconductor apparatus 10A having the structure illustrated in FIG. 1. In case of producing the vertical semiconductor apparatus 10A, as shown in FIG. 9A for example, a p+ type wafer (second conductive type semiconductor substrate (p+-Sub.)) 41 having the thickness of approximately 600 μm is prepared. Then, an n+ type epitaxial layer (first conductive type buffer layer) 42 and an n− type epitaxial layer (first conductive semiconductor substrate) 43 are formed on the surface of the wafer 41 in the mentioned order. In this case, the thickness (D3) of the n+ type epitaxial layer 42 is set to approximately 1 μm, and the thickness (D2+D5) of the n− type epitaxial layer 43 is set to approximately 58 μm.

Then, as shown in FIG. 9B for example, the MOS structure 32 having the planar gate structure is formed to the surface portion of the n− type epitaxial layer 43.

Subsequently, as shown in FIG. 9C for example, the p+ type wafer 41 is removed by the polishing method or the like while leaving the thickness of approximately 1 μm, thereby forming the p+ type collector layer 17. As a result, there is formed the IGBT having the thickness (D1) of approximately 60 μm, in which the n− type epitaxial layer 43 being determined as the n− type semiconductor substrate and the n+ type epitaxial layer 42 being determined as the n+ type buffer layer.

After forming the IGBT in this manner, as shown in FIG. 9D for example, the joint substrate 22 having the thickness of 340 μm is brought into contact with the p+ type collector layer 17. Then, the IGBT and the joint substrate 22 are joined to each other by, e.g., heating.

Further, the substrate electrode 23 is formed on the non-joining surface of the joint substrate 22 with respect to the p+ type collector layer 17 according to needs. Then, the vertical semiconductor apparatus 10A having the above-described structure is finally completed by performing separation/division in accordance with each IGBT. The vertical semiconductor apparatus having the structure equal to that of the vertical semiconductor apparatus 10A illustrated in FIG. 1 can be likewise obtained by such a process.

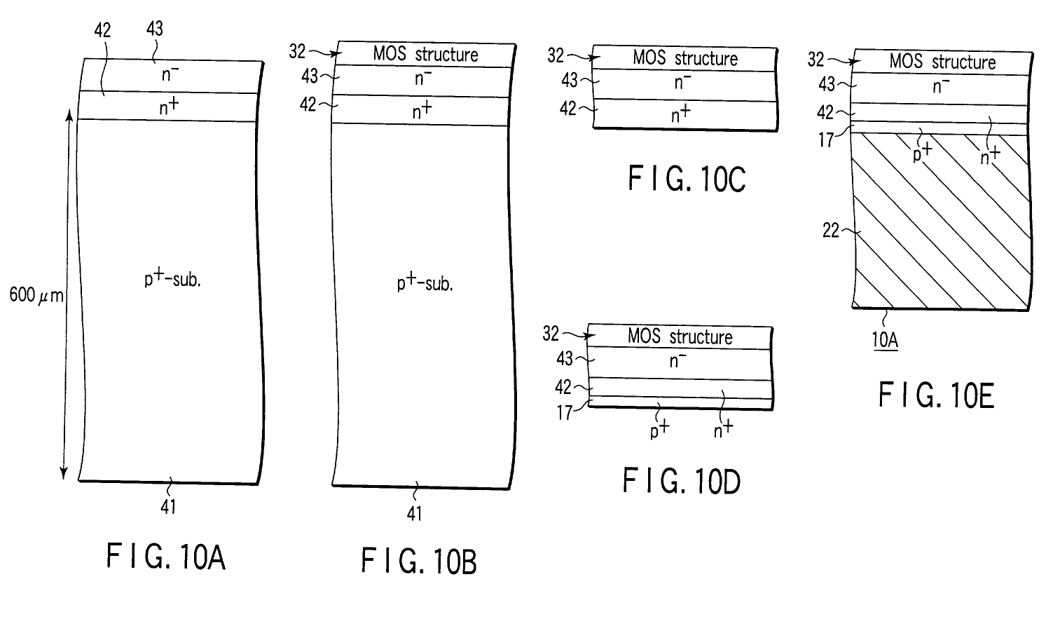

FIGS. 10A to 10E show still another method for manufacturing the vertical semiconductor apparatus having the structure depicted in FIG. 1. In case of producing the vertical semiconductor apparatus 10A, as shown in FIG. 10A for example, the p+ type wafer (second conductive semiconductor substrate (p+-Sub.)) 41 having the thickness of approximately 600 μm is prepared. Then, the n+ type epitaxial layer (first conductive buffer layer) 42 and the n− type epitaxial layer (first conductive semiconductor substrate) 43 is formed on the surface of the wafer 41 in the mentioned order. In this case, the thickness of the epitaxial layer 42 (D3+D4) is set to approximately 2 μm, and the thickness of the n− type epitaxial layer 43 (D2+D5) is set to approximately 58 μm.

Subsequently, as shown in FIG. 10B for example, the MOS structure 32 having the planar gate structure is formed at the surface portion of the n− type epitaxial layer 43.

Then, as shown in FIG. 10C for example, all of the p+ type wafer 41 is removed by the polishing method or the like.

Thereafter, as shown in FIG. 10D for example, the p+ type collector layer 17 is formed with the thickness of approximately 1 μm on the surface of the n+ type epitaxial layer 42 on which the n− type epitaxial layer 43 is not formed. As a result, there is formed the IGBT having the thickness (D1) of approximately 60 μm with the n− type epitaxial layer 43 being determined as the n− type semiconductor substrate and the n+ type epitaxial layer 42 being determined as the n+ type buffer layer.

In this manner, after forming the IGBT, as shown in FIG. 10E for example, the joint substrate 22 having the thickness of 340 μm is brought into contact with the p+ type collector layer 17. Then, the IGBT and the joint substrate 22 are jointed to each other by, e.g., heating.

Moreover, the substrate electrode 23 is formed on the non-joining surface of the joint substrate 22 relative to the p+ type collector layer 17 according to needs. In addition, the vertical semiconductor apparatus 10A having the above-described structure is finally completed by performing separation/division in accordance with each IGBT. The vertical semiconductor apparatus having the structure equal to that of the vertical semiconductor apparatus 10A illustrated in FIG. 1 can be obtained by such a process.

This method is very simple as compared with the above-described method which forms the p+ type collector layer 17 having the thickness of approximately 1 μm by eliminating a part of the p+ type wafer 41 (see FIGS. 9A to 9D). That is, it is particularly useful when it is hard to accurately control the thickness of the p+ type collector layer 17.

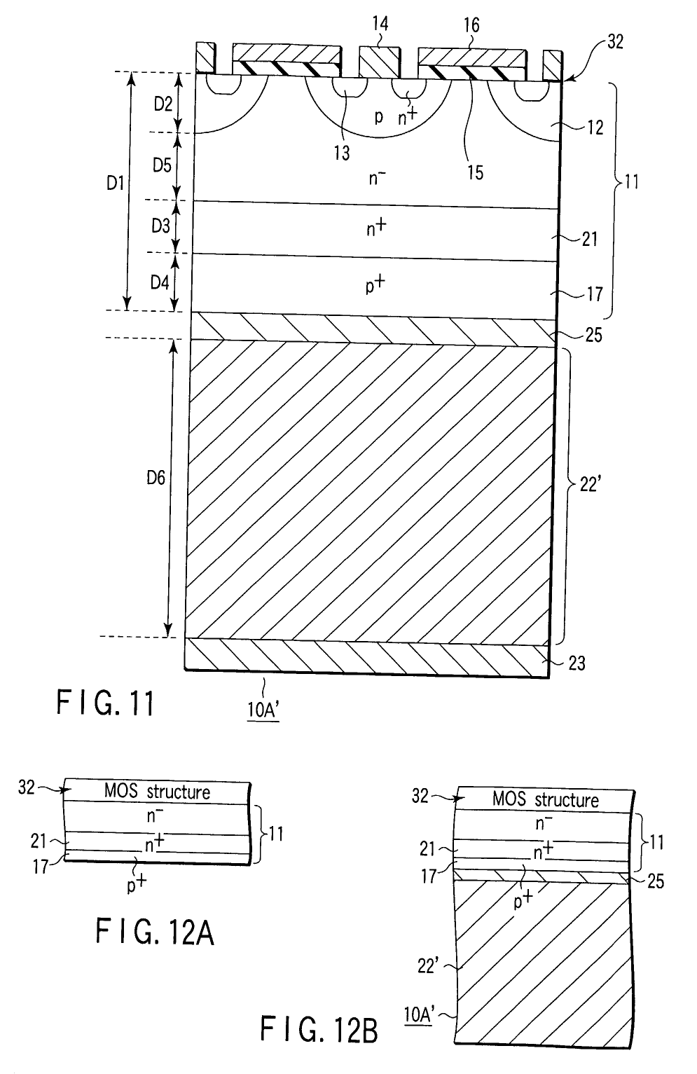

FIG. 11 shows an example (vertical semiconductor apparatus 10A′) where the semiconductor layer is used as the joint substrate in the vertical semiconductor apparatus 10A according to the first embodiment of the present invention.

In FIG. 11, a collector electrode (second electrode) 25 is connected to the lower surface (back side) of the n− type semiconductor substrate 11 on which the MOS structure 32 having the planar gate structure is formed. In addition, the joint substrate 22′ is joined to the collector electrode 25. In this case, as the joint substrate 22′, besides a metal such as Al, there is used p type or n type monocrystal silicon or polycrystal (poly-) silicon with high impurity concentration, which is used as a conductive material, for example. In particular, the joint substrate 22′ is configured not to partially have the impurity diffusion layer obtained by ion implantation method or the like. Additionally, as the collector electrode 25, a metal such as Al or poly-silicon or amorphous-silicon with high impurity concentration is used for example.

In the vertical semiconductor apparatus 10A′ having such a structure, the advantages substantially similar to those of the vertical semiconductor apparatus 10A shown in FIG. 1 can be likewise obtained. In particular, when the collector electrode 25 and the joint substrate 22′ are formed by using a substance equal to that of the IGBT (same element), i.e., silicon, physical properties such as a thermal expansion coefficient of each part can be uniformized. As a result, deformation with respect to the thermal stress can be suppressed. However, in case of operating the IGBT at a high speed, it is desirable to use a metal for the collector electrode 25 and the joint substrate 22′.

FIGS. 12A and 12B show a method for manufacturing the vertical semiconductor apparatus 10A′ having the structure illustrated in FIG. 11. In case of producing the vertical semiconductor apparatus 10A′, the collector electrode 25 is formed on the surface of the n− type semiconductor substrate 11 on which the MOS structure 32 is not formed after manufacturing the IGBT by the process illustrated in, e.g., FIGS. 8A to 8C (see FIG. 12A).

Subsequently, the joint substrate 22′ having the thickness of 340 μm is brought into contact with the non-joining surface of the collector electrode 25 with respect to the n− type semiconductor substrate 11. Then, the collector electrode 25 is dissolved or diffused by, e.g., heating. By doing so, the IGBT and the joint substrate 22′ are joined to each other through the collector electrode 25 (see FIG. 12B).

Further, the substrate electrode 23 is formed on the non-joining surface of the joint substrate 22′ with respect to the collector electrode 25 according to needs. Then, the vertical semiconductor apparatus 10A′ having the structure illustrated in FIG. 11 is finally completed by performing separation/division in accordance with each IGBT.

It is to be noted that the first embodiment of the present invention is not restricted to the IGBT manufactured by the process illustrated in FIGS. 8A to 8C. As the IGBT, it is possible to use one manufactured by the process illustrated in FIGS. 9A to 9C or FIGS. 10A to 10D.

(Second Embodiment)

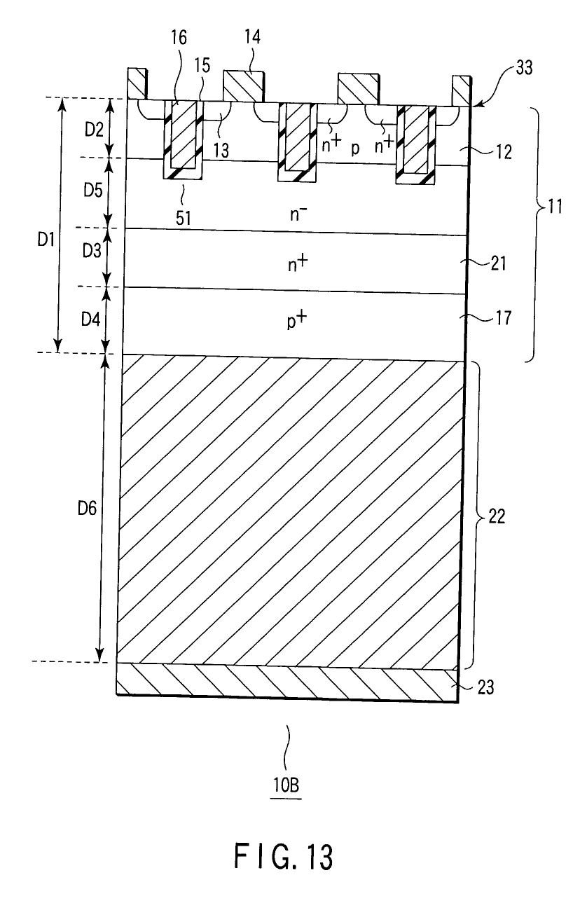

FIG. 13 shows a structural example of a vertical semiconductor apparatus 10B according to a second embodiment of the present invention. It is to be noted that description will be given as to the example where the embodiment of the present invention is applied to the punch-through type IGBT having the trench gate structure.

In FIG. 13, a p type base layer 12 which is of the second conductive type is formed in a surface area of an n− type semiconductor substrate 11 which is of the first conductive type (for example, monocrystal silicon). A plurality of n+ type emitter layers 13 are formed in the surface area of the p type base layer 12. A plurality of emitter electrodes 14 are arranged on the surface of the n− type semiconductor substrate 11. Each of the emitter electrodes 14 is connected to the p type base layer 12 and the n+ type emitter layer 13. Furthermore, a plurality of trenches 51 are formed in the surface area of the p type base layer 12. Each trench 51 is formed with the depth which pierces the n+ type emitter layer 13 and the p type base layer 12 and reaches the n− type semiconductor substrate 11. A gate electrode 16 is embedded in each trench 51 with each gate insulation film 15 interposed therebetween. In this manner, an MOS (Metal Oxide Semiconductor) structure 33 having the trench gate structure is formed at the surface portion of the n− type semiconductor substrate 11.

On the other hand, an n+ type buffer layer 21 and the p+ type collector layer (carrier injection layer) 17 are formed in the lower (back side) area of the n− type semiconductor substrate 11, i.e., on the surface thereof where the MOS structure 33 is not formed. As a result, there can be realized the punch-through type IGBT (semiconductor element) having a so-called trench gate structure which becomes conductive by movement of the carrier in the vertical direction of the n− type semiconductor substrate 11. The punch-through type IGBT having the trench gate structure has the lower loss than the punch-through type IGBT having the planar gate structure described in the first embodiment.

Moreover, a joint substrate 22 is joined to the lower surface (back side) of the n− type semiconductor substrate 11. That is, this joint substrate 22 is provided to contact with the p+ type collector layer 17. The joint substrate 22 is formed by using a metal (conductive material) such as aluminium (Al). In addition, the substrate electrode (first electrode) 23 can be provided to the non-joining surface of the joint substrate 22 with respect to the n− type semiconductor substrate 11 according to needs. However, the substrate electrode 23 is formed by using nickel (Ni) or gold (Au) which is superior to the joint substrate 22 in the joint property with respect to solder when mounting this vertical semiconductor apparatus 10B. That is, in cases where the joint substrate 22 is formed by using a metal having the excellent joint property with respect to solder, the substrate electrode 23 does not have to be provided.

In case of this embodiment, the vertical semiconductor apparatus 10B is formed so as to have the thickness of approximately 400 μm as a whole.

In the vertical semiconductor apparatus 10B having such a structure, when the thickness D1 of the n− type semiconductor substrate 11 is, e.g., 60 μm, the thickness D6 of the joint substrate 22 to be joined is, e.g., approximately 340 μm (thickness not less than 200 μm). By doing so, the cost can be reduced as compared with the case of forming the epitaxial layer, the sufficient mechanical strength can be obtained, and the high-performance IGBT with less loss can be provided.

It is to be noted that the vertical semiconductor apparatus 10B can be formed by the processes illustrated in FIGS. 8A to 8D, FIGS. 9A to 9D and FIGS. 10A to 10E. That is, the p type base layer 12 is formed with the thickness of approximately 3 μm in the surface area of the n− type wafer 31 by diffusion of impurities. Thereafter, the emitter electrode 14 is formed on the surface of the n− wafer 31. Then, the n+type emitter layer 13 is formed in the surface area of the p type base layer 12 by diffusion of impurities of the n+ type emitter layer 13 with the emitter electrode 14 being used as a mask. Thereafter, the trench 51 is formed in the surface area of the p type base layer 12, and the gate insulation film 15 and the gate electrode 16 are embedded in the trench 51. Then, the MOS structure 33 having the trench gate structure is formed at the surface portion of the n− type wafer 31.

Thereafter, the process illustrated in FIGS. 8B to 8D, FIGS. 9C to 9D and FIGS. 10C to 10E is similarly carried out. By doing so, the vertical semiconductor apparatus 10B can be easily realized.

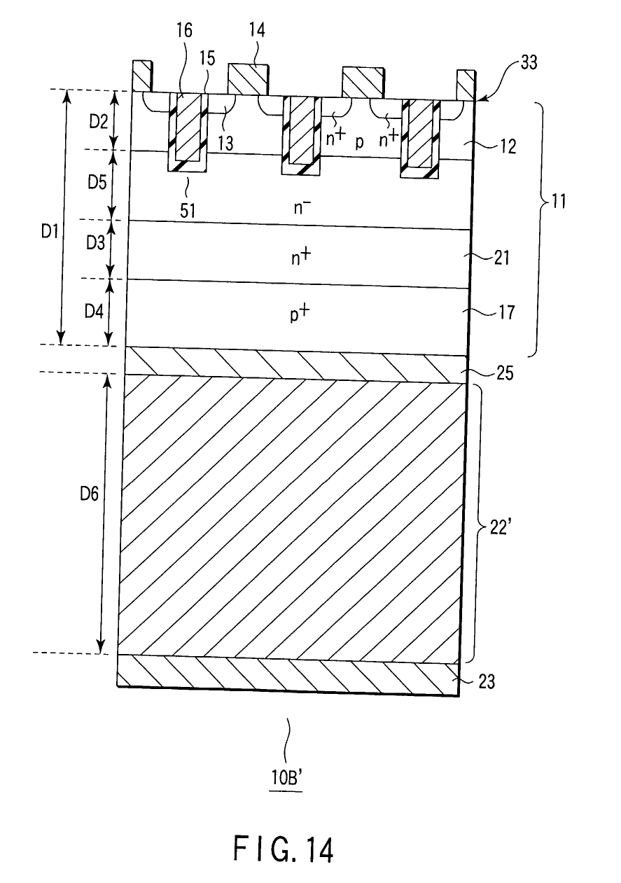

FIG. 14 shows an example (vertical semiconductor apparatus 10B′) where the semiconductor layer is used for the joint substrate in the vertical semiconductor apparatus 10B according to the second embodiment of the present invention.

In FIG. 14, the collector electrode (second electrode) 25 is connected to the lower surface (back side) of the n− type semiconductor substrate 11 on which the MOS structure 33 having the trench gate structure is formed. Then, the joint substrate 22′ is joined to the collector electrode 25. In this case, as the joint substrate 22′, besides a metal such as Al, the high-density p type or n type monocrystal silicon or polycrystal (poly-) silicon is used as a conductive material for example. In particular, the joint substrate 22′ is configured not to partially have the impurity diffusion layer obtained by ion implantation or the like. In addition, as the collector electrode 25, for example, a metal such as Al or high-density polysilicon or amorphous silicon is used.

In the vertical semiconductor apparatus 10B′ having such a structure, the advantages similar to those of the vertical semiconductor apparatus 10B illustrated in FIG. 13 can be obtained. In particular, when the collector electrode 25 and the joint substrate 22′ are formed by using the substance equal to that of the IGBT (same element), namely, silicon, physical properties such as a thermal expansion coefficient of each part can be uniformized. As a result, deformation with respect to thermal stress can be suppressed. However, when the IGBT is operated at a high speed, it is desirable to use the metal for the collector electrode 25 and the joint substrate 22′.

Incidentally, the vertical semiconductor apparatus 10B′ can be easily formed by the process substantially similar to that illustrated in FIGS. 12A and 12B for example.

(Third Embodiment)

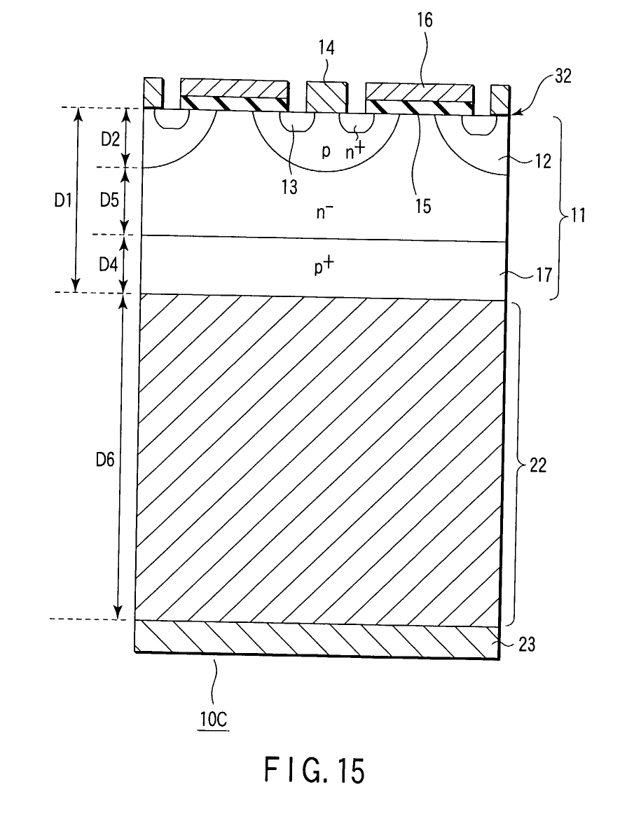

FIG. 15 shows a structural example of a vertical semiconductor apparatus 10C according to a third embodiment of the present invention. Incidentally, here, description will be given as to the example where the embodiment of the present invention is applied to the IGBT having the planar gate structure. Moreover, this IGBT is of a non-punch-through type that the buffer layer is not provided to a part of the substrate.

In FIG. 15, a plurality of p type base layers 12 which are of the second conductive type are formed in the surface area of the n− type semiconductor substrate (for example, monocrystal silicon) 11 which is of the first conductive type. A plurality of n+ type emitter layers 13 are formed in the surface area of the p type base layer 12. A plurality of emitter electrodes 14 are arranged on the surface of the n− type semiconductor substrate 11. Each emitter electrode 14 is connected to the p type base layer 12 and the n+type emitter layer 13. Further, a plurality of gate electrodes 16 are formed on the surface of the n− type semiconductor substrate 11 with the gate insulation film 15 interposed therebetween. Each gate electrode 16 is adjacent to the n− type semiconductor substrate 11, the p type base layer 12 and the n+ type emitter layer 13. In this manner, an MOS (Metal Oxide Semiconductor) structure 32 having the planar gate structure is formed at the surface portion of the n-type semiconductor substrate 11.

On the other hand, a p+ type collector layer (carrier injection layer) 17 is formed in a lower (back side) area of the n− type semiconductor substrate 11, namely, the surface thereof where the MOS structure 32 is not formed. As a result, there is realized a non-punch-through type IGBT (semiconductor element) having a so-called planar gate structure which becomes conductive by movement of the carrier in the vertical direction of the n− type semiconductor substrate 11.

Furthermore, a joint substrate 22 is joined to the lower surface (back side) of the n− type semiconductor substrate 11. That is, this joint substrate 22 is provided to contact with the p+ type collector layer 17. The joint substrate 22 is formed by using a metal (conductive material) such as aluminium (Al). Further, a substrate electrode (first electrode) 23 can be formed on the non-joining surface of the joint substrate 22 with respect to the n− type semiconductor substrate 11 according to needs. However, the substrate electrode 23 is formed of nickel (Ni) or gold (Au) which is superior to the joint substrate 22 in the joint property with respect to solder when mounting the vertical semiconductor apparatus 10C. That is, when the joint substrate 22 is formed by using a metal with the excellent joint property with solder, the substrate electrode 23 does not have to be provided.

In case of this embodiment, the vertical semiconductor apparatus 10C is formed so as to have the thickness of approximately 400 μm as a whole.

In the vertical semiconductor apparatus 10C having such a structure, for example, assuming that the withstand voltage of the IGBT is 600 V, approximately 1.5×10¹⁴ cm⁻³ is desirable for the density of the n-type semiconductor substrate 11.

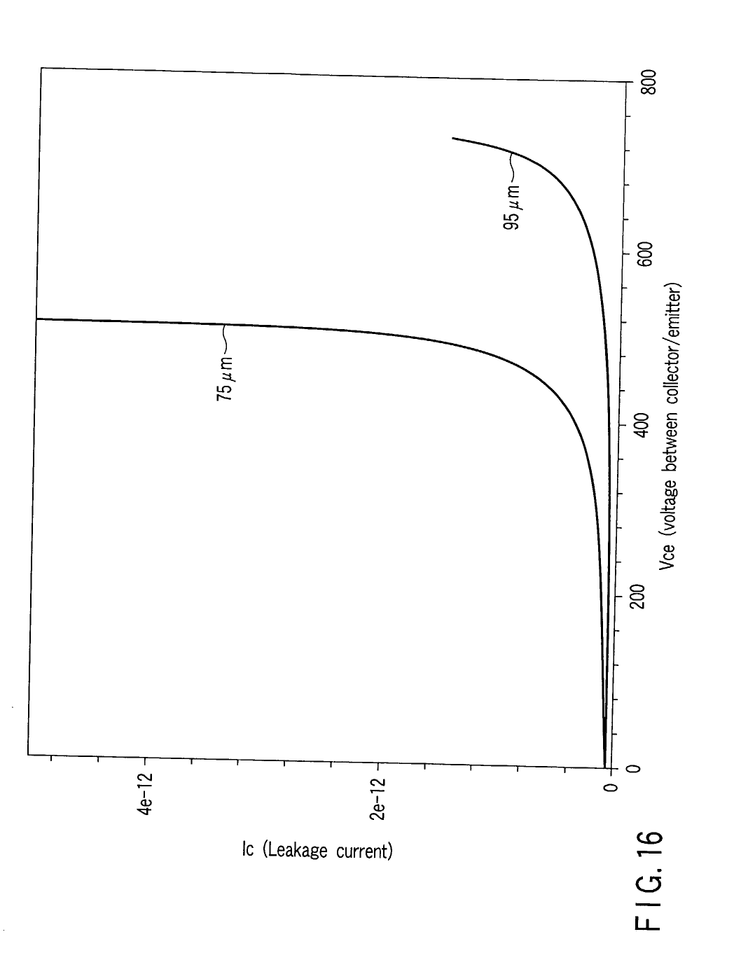

FIG. 16 shows a result of simulating the withstand voltage at the time of turn-off when the withstand voltage of the IGBT is 600 V. Incidentally, here, the cases where the thickness of D5 in FIG. 15 is 75 μm and where it is 95 μm are illustrated. As apparent from FIG. 16, as the thickness D5 obtained by subtracting the thickness D2 of the p type base layer 12 and the thickness D4 of the p+ type collector layer 17 from the thickness D1 of the n− type semiconductor substrate 11, the thickness of approximately 95 μm is desirable. When the thickness of D5 is set to a value lower than 95 μm, e.g., 75 Am, the breakdown occurs with a voltage of not more than 600 V, which results in insufficient withstand voltage.

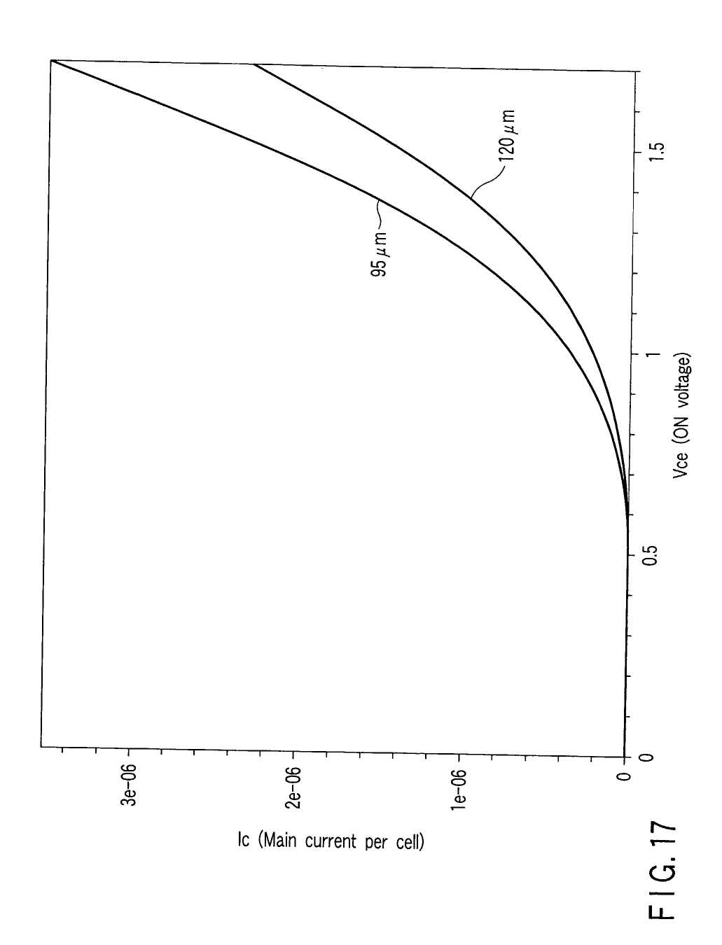

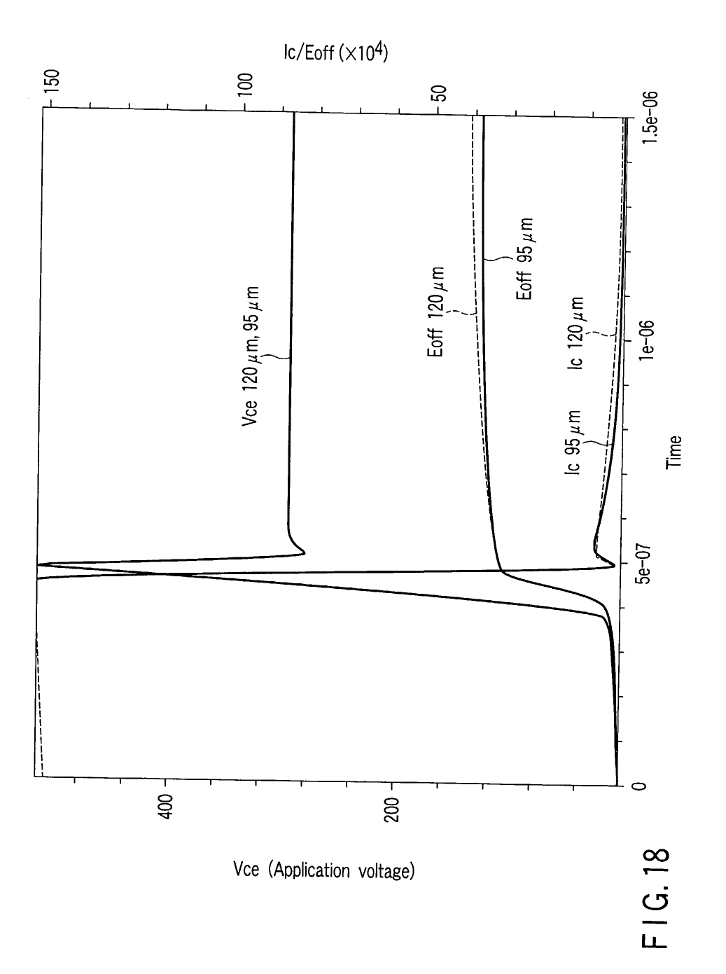

FIG. 17 shows a result of simulating the ON voltage of the IGBT, and FIG. 18 shows a result of simulating the loss (Eoff) at the time of turn-off. Incidentally, here, the cases where the thickness of D5 in FIG. 15 is 120 μm and where it is 95 μm are illustrated. When the thickness of D5 is set to a value higher than 95 μm, e.g., 120 μm, as apparent from FIG. 17, the saturation voltage between the emitter and the collector, i.e., the ON voltage is increased. Further, as apparent from FIG. 18, the loss at the time of turn-off is increased. That is, in the non-punch-through type IGBT, the optimum value of the thickness D5 exists in accordance with the necessary withstand voltage.

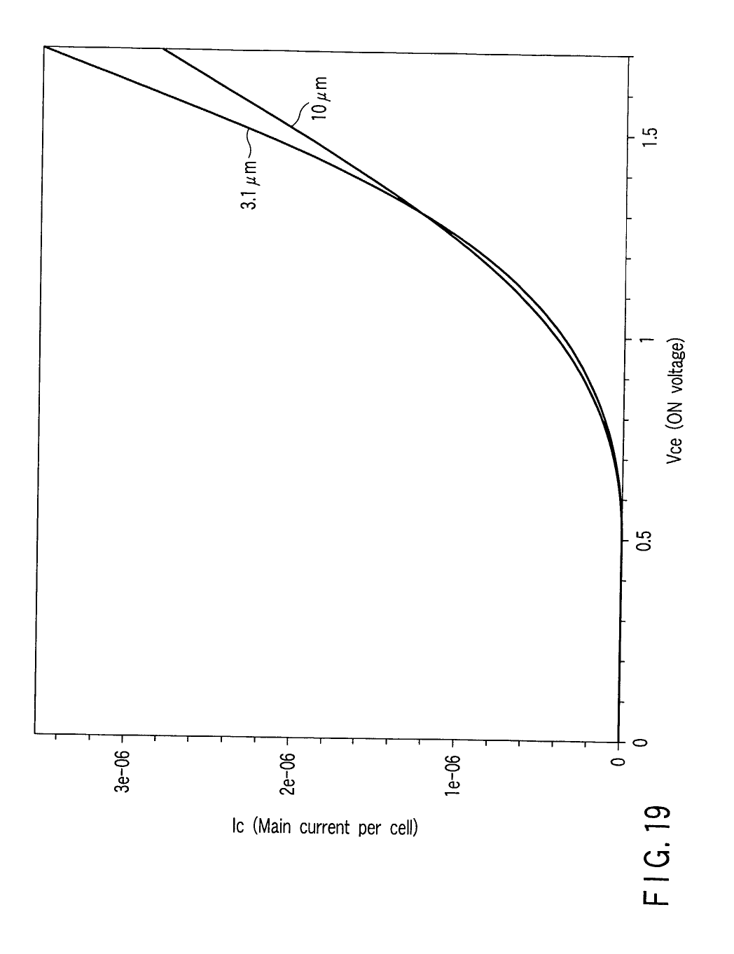

FIG. 19 shows a result of simulating the ON voltage of the IGBT. Incidentally, here, the cases where the thickness D2 of the p type base layer 12 is 3.1 μm and it is 10 μm are illustrated. As apparent from FIG. 19, it is preferable to reduce the thickness D2 of the p type base layer 12 so as to maintain the withstand voltage, and the thickness of, e.g., 3 μm is desirable. When the thickness D2 of the p type base layer 12 is set to a large value, e.g., 10 μm, the loss in the ON state is increased.

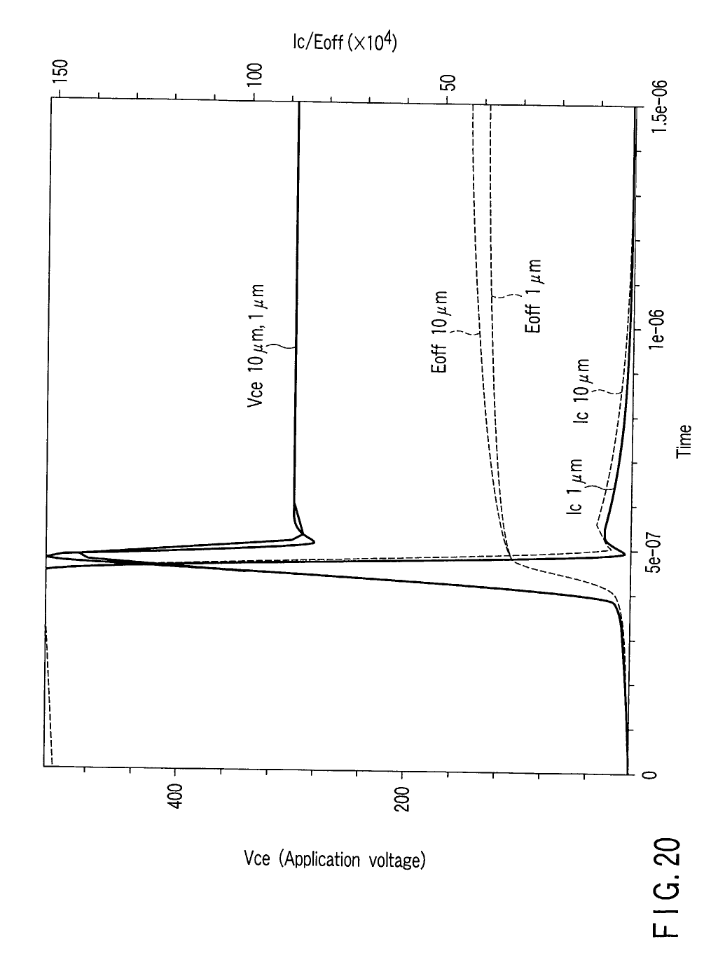

FIG. 20 shows a result of simulating the loss at the time of turn-off of the IGBT. Incidentally, here, the cases where the thickness D4 of the p+ type collector layer 17 is 1 μm and where it is 10 μm are illustrated. As apparent from FIG. 20, it is preferable to reduce the thickness D4 of the p+ type collector layer 17 so as to be capable of sufficiently injecting the carrier in the ON state, and the thickness of, e.g., approximately 1 μm (depth not more than 10 μm) is desirable. When the thickness D4 of the p+ type collector layer 17 is set to a large value, e.g., 10 μm, the loss at the time of turn-off is increased.

Based on this, in case of producing the non-punch-through type IGBT having the planar gate structure whose withstand voltage is 600 V, the thickness D1 of the n− type semiconductor substrate 11 is set to, e.g., 100 μm. As a result, the IGBT with less loss can be realized irrespective of the joint substrate 22.

Here, when the material of the n− type semiconductor substrate 11 is monocrystal silicon and the IGBT whose withstand voltage is 600 V is created, determining the thickness D1 of the n− type semiconductor substrate 11 as 100 μm can realize the IGBT with less loss. However, when the thickness D1 of the n− type semiconductor substrate 11 is not more than 100 am, the mechanical strength is insufficient. Therefore, the product may be readily destroyed by an impact shock from the outside during or after manufacture. Thus, the joint substrate 22 is joined to the IGBT, and the thickness D6 of the joint substrate 22 is set to, e.g., approximately 300 μm (thickness of not less than 200 μm). As a result, the cost can be reduced as compared with the case of forming the epitaxial layer, the sufficient mechanical strength can be obtained, and the high-performance IGBT with less loss can be obtained.

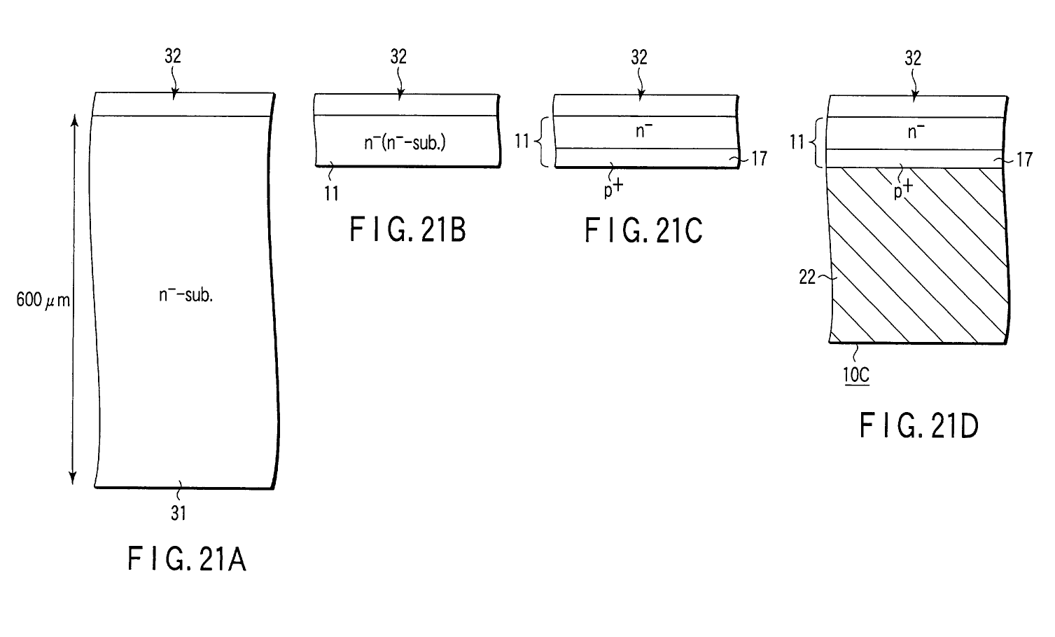

FIGS. 21A to 21D show a method for producing the vertical semiconductor apparatus 10C illustrated in FIG. 15. When producing the vertical semiconductor apparatus 10C, as shown in FIG. 21A for example, an n− type wafer (first conductive type semiconductor substrate (n−-Sub.)) 31 having the thickness of approximately 600 μm is prepared. Then, an MOS structure 32 having the planar gate structure is formed at the surface portion of the wafer 31. That is, a plurality of p type base layers 12 are formed in the surface area of the n− type wafer 31 so as to have the thickness of approximately 3 μm by diffusion of impurities. Thereafter, a gate insulation film 15 and a gate electrode 16 are formed on the surface of the n− type wafer 31. Furthermore, an emitter electrode 14 is formed on the surface of the n− type wafer 31 before and after formation of the gate electrode 16. Moreover, an n+ type emitter layer 13 is formed in the surface area of the p type base layer 12 by diffusion of impurities with the gate electrode 16 and the emitter electrode 14 being used as masks. In this manner, the MOS structure 32 having the planar gate structure is formed at the surface portion of-the n− type wafer 31.

Subsequently, as shown in FIG. 21B for example, a part of the surface of the n− type wafer 31 on which the MOS structure is not formed is removed by the polishing method or the like. As a result, the n− type semiconductor substrate 11 is formed. In this case, the thickness D1 of the n− type semiconductor substrate 11 excluding the gate electrode 16 and the emitter electrode 14 is set to approximately 100 μm.

Then, as shown in FIG. 21C for example, the p+ type collector layer 17 is formed on the surface of the n− type semiconductor substrate 11 on which the MOS structure 32 is not formed. At this moment, the p+ type collector layer 17 is formed so as to have a thickness of approximately 1 μm by the ion implantation method instead of the epitaxial growth method.

In this manner, after forming the IGBT, as shown in FIG. 21D for example, the joint substrate 22 having the thickness of 300 μm is brought into contact with the surface of the n− type semiconductor substrate 11 on which the MOS structure 32 is not formed. In addition, the IGBT and the joint substrate 22 are joined to each other by, e.g., heating.

Additionally, the substrate electrode 23 is formed on the non-joining surface of the joint substrate 22 with respect to the n− type semiconductor substrate 11 according to needs. Further, the vertical semiconductor apparatus 10C having the structure shown in FIG. 15 is finally completed by separation/division in accordance with each IGBT.

In this embodiment, when manufacturing the vertical semiconductor apparatus 10C, a wafer having the thickness of 600 μm is used. Therefore, the sufficient mechanical structure can be assured not only after completion of the vertical semiconductor apparatus 10C but with respect to warpage or an impact shock from the outside during manufacture.

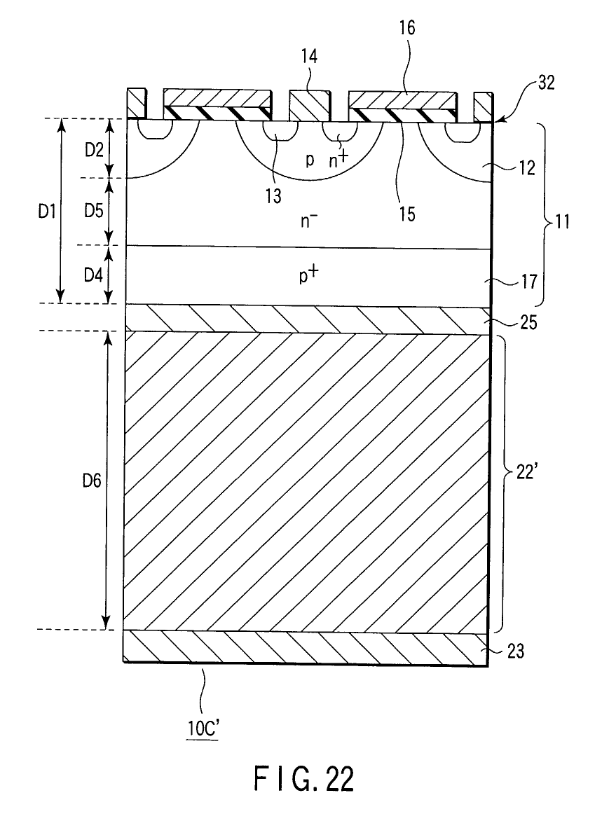

FIG. 22 shows an example (vertical semiconductor apparatus 10C′) where the semiconductor layer is used for the joint substrate in the vertical semiconductor apparatus 10C according to the third embodiment of the present invention.

In FIG. 22, a collector electrode (second electrode) 25 is connected to the lower surface (back side) of the n− type semiconductor substrate 11 to which the MOS structure 32 having the planar gate structure is formed. Further, the joint substrate 22′ is joined to the collector electrode 25. In this case, as the joint substrate 22′, besides a metal such as Al, high-density p type or n type monocrystal silicon or polycrystal (poly-) silicon as a conductive material is used. In particular, the joint substrate 22′ is configured not to partially have the impurity diffusion layer obtained by ion implantation or the like. Further, as the collector electrode 25, a metal such as Al, high-density polysilicon or amorphous silicon is used for example.

In the vertical semiconductor apparatus 10C′ having such a structure, the advantages substantially similar to those of the vertical semiconductor apparatus 10C illustrated in FIG. 15 can be obtained. In particular, when the collector electrode 25 and the joint substrate 22′ are formed of a substance equal to that of the IGBT (same element), namely, silicon, physical properties such as a thermal expansion coefficient at each part can be uniformized. As a result, deformation with respect to the thermal stress can be suppressed. However, when the IGBT is operated at a high speed, it is preferable to use a metal for the collector metal 25 and the joint substrate 22′.

(Fourth Embodiment)

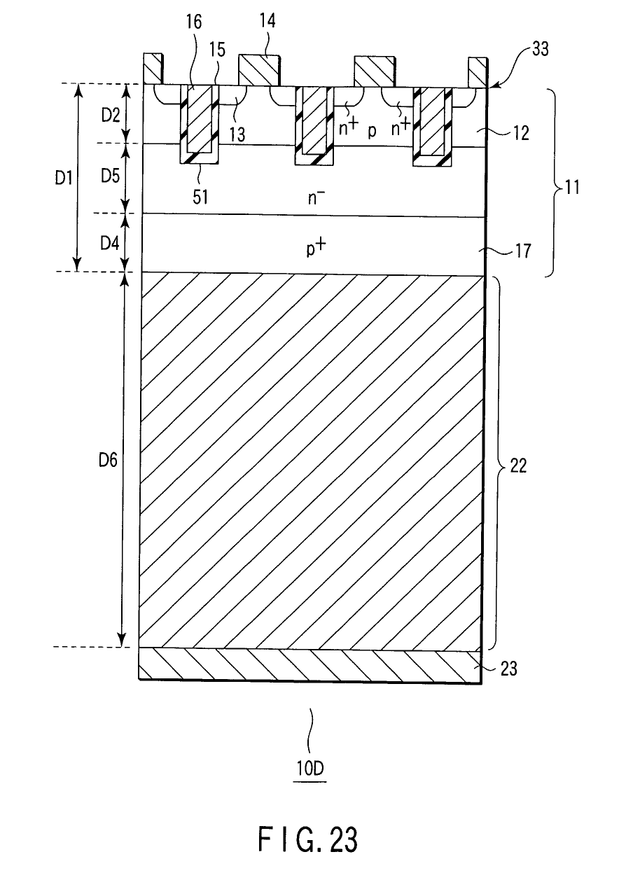

FIG. 23 shows a structural example of the vertical semiconductor apparatus 10D according to a fourth embodiment of the present invention. It is to be noted that description will be given as to the example where the embodiment of the present invention is applied to the non-punch-through type IGBT having the trench gate structure.

In FIG. 23, a p type base layer 12 which is of the second conductive type is formed in the surface area of the n− type semiconductor substrate (for example, monocrystal silicon) 11 which is of the first conductive type. A plurality of n+ type emitter layers 13 are formed in the surface area of the p type base layer 12. A plurality of emitter electrodes 14 are arranged on the surface of the n− type semiconductor substrate 11. Each emitter electrode 14 is connected to the p type base layer 12 and the n+ type emitter layer 13. Further, a plurality of trenches 51 are formed in the surface area of the p type base layer 12. Each trench 51 is formed with a depth which pierces the n+ type emitter layer 13 and the p type base layer 12 and reaches the n− type semiconductor substrate 11. A gate electrode 16 is embedded in each trench with the gate insulation film 15 interposed therebetween. In this embodiment, an MOS (Metal Oxide Semiconductor) structure 33 having the trench gate structure is formed at the surface portion of the n− type semiconductor substrate 11.

On the other hand, a p+ type collector layer (carrier injection layer) 17 is formed in a lower (back side) area of the n− type semiconductor substrate 11, i.e., on the surface thereof where the MOS structure 33 is not formed. As a result, there is realized a non-punch-through type IGBT (semiconductor element) having a so-called trench gate structure which becomes conductive by movement of the carrier in the vertical direction of the n− type semiconductor substrate 11. The non-punch-through type IGBT having the trench gate structure has lower losses than the non-punch-through type IGBT having the planar gate structure described in connection with the third embodiment.

Furthermore, a joint substrate 22 is joined to the lower surface (back side) of the n− type semiconductor substrate 11. That is, the joint substrate 22 is provided to contact with the p+ type collector layer 17. The joint substrate 22 is formed by using a metal (conductive material) such as aluminium (Al). Moreover, a substrate electrode (first electrode) 23 can be provided on the non-joining surface of the joint substrate 22 with respect to the n− type semiconductor substrate 11 according to needs. However, the substrate electrode 23 is formed of nickel (Ni) or gold (Au) which is superior to the joint substrate 22 in the joint property with respect to solder when mounting the vertical semiconductor apparatus 10D. That is, when the joint substrate 22 is formed by using a metal having the excellent property with respect to solder, the substrate electrode 23 does not have to be provided.

In case of this embodiment, the vertical semiconductor apparatus 10D is formed so as to have a thickness of, e.g., approximately 400 μm as a whole.

In the vertical semiconductor apparatus 10D having such a structure, when the thickness D1 of the n− type semiconductor substrate 11 is, e.g., 100 μm, the thickness D6 of the joint substrate 22 to be joined is set to, e.g., approximately 300 μm (thickness of not less than 200 μm). By doing so, the cost can be reduced as compared with the case of forming the epitaxial layer, the sufficient mechanical strength can be obtained, and the high-performance IGBT with less loss can be provided.

It is to be noted that the vertical semiconductor apparatus 10D can be formed by the process substantially similar to that of the process illustrated in FIGS. 8A to 8D, FIGS. 9A to 9D and FIGS. 10A to 10E, for example.

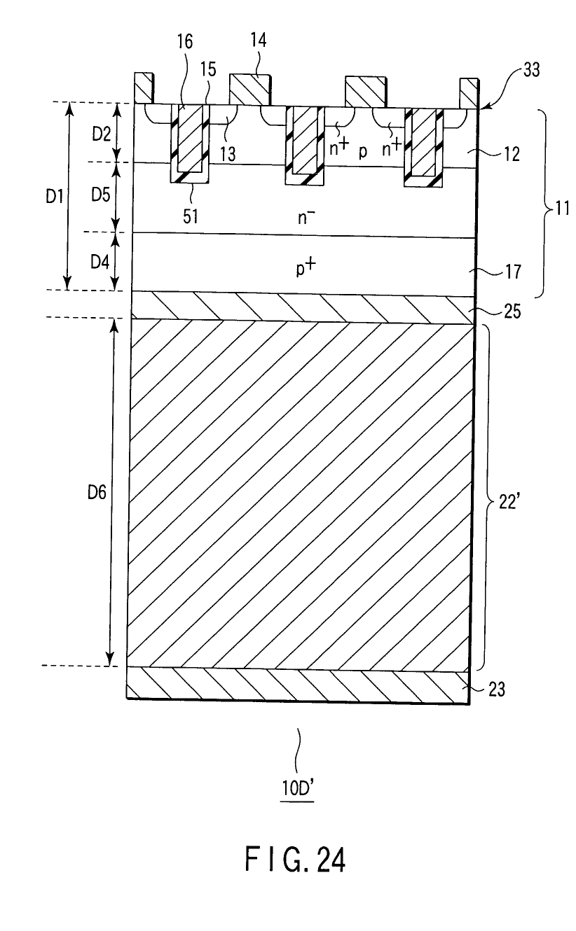

FIG. 24 shows an example (vertical semiconductor apparatus 10D′) where the semiconductor layer is formed for the joint substrate in the vertical semiconductor apparatus 10D according to a fourth embodiment of the present invention.

In FIG. 24, a collector electrode (second electrode) 25 is connected to the lower surface (back side) of he n− type semiconductor substrate 11 to which an MOS structure 33 having a trench gate structure is formed. In addition, the joint substrate 22′ is joined to the collector electrode 25. In this case, as the joint substrate 22′, besides a metal such as Al, high-density p type or n type monocrystal silicon or polycrystal (poly-) silicon is used as a conductive material, for example. In particular, the joint substrate 22′ is configured not to partially have the impurity diffusion layer obtained through ion implantation or the like. Additionally, as the collector electrode 25, a metal such as Al, high-density polysilicon or amorphous silicon is used.

In the vertical semiconductor apparatus 10D′ having such a structure, advantages substantially similar to those of the vertical semiconductor apparatus 10D illustrated in FIG. 23 can be obtained. In particular, when the collector electrode 25 and the joint substrate 22′ are formed by using a material equal to that of the IGBT (same element), namely, silicon, physical properties such as a thermal expansion coefficient of each part can be uniformized. As a result, deformation with respect to thermal stress can be suppressed. However, when the IGBT is operated at a high speed, it is preferable to use a metal for the collector electrode 25 and the joint substrate 22′.

(Fifth Embodiment)

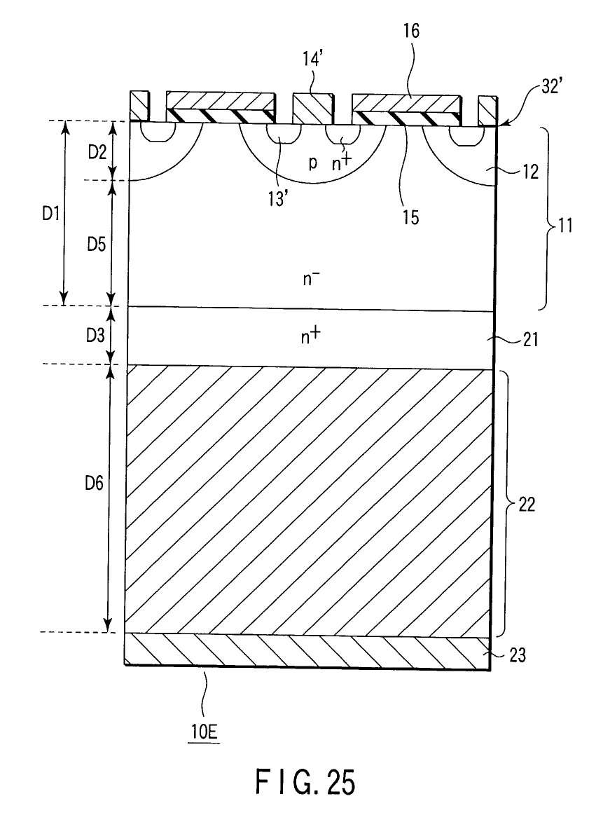

FIG. 25 shows a structural example of a vertical semiconductor apparatus 10E according to a fifth embodiment of the present invention. It is to be noted that description will be given as to the case where the embodiment of the present invention is applied to a punch-through type MOSFET having the planar gate structure.

In FIG. 25, a plurality of p type base layers 12 which are of the second conductive type are formed in the surface area of an n− type semiconductor substrate (for example, monocrystal silicon) 11 which is of the first conductive type. A plurality of n+ type source layers 13′ are formed in the surface area of the p type base layer 12. A plurality of source electrodes 14′ are arranged on the surface of the n− type semiconductor substrate 11. Each source electrode 14′ is connected to the p type base layer 12 and the n+ type source layer 13′. In addition, a plurality of gate electrodes 16 are formed on the surface of the n− type semiconductor substrate 11 with a gate insulation film 15 interposed therebetween. Each gate electrode 16 is adjacent to the n− type semiconductor substrate 11, the p type base layer 12 and the n+ type source layer 13′. In this manner, an MOS (Metal Oxide Semiconductor) structure 32′ having a planar gate structure is formed at the surface portion of the n-type semiconductor substrate 11.

On the other hand, an n+ type buffer layer 21 is formed in a lower (back side) area of the n− type semiconductor substrate 11, namely, on the surface thereof where the MOS structure 32′ is not formed. As a result, there is realized a punch-through type MOSFET (semiconductor element) having a so-called planar gate structure which becomes conductive by movement of the carrier in the vertical direction of the n− type semiconductor substrate 11.

Additionally, the joint substrate 22 is joined on the lower surface (back side) of the n− type semiconductor substrate 11. That is, the joint substrate 22 is provided to contact with the n+ type buffer layer 21. The joint substrate 22 is formed by using a metal (conductive material) such as aluminium (Al). Further, a substrate electrode (first electrode) 23 can be formed on the non-joining surface of this joint substrate 22 with respect to the n− type semiconductor substrate 11. However, the substrate electrode 23 is formed of nickel (Ni) or gold (Au) which is superior to the joint substrate 22 in the joint property with respect to solder when mounting the vertical semiconductor apparatus 10E. That is, when the joint substrate 22 is formed by using a metal with the excellent joint property with respect to solder, the substrate electrode 23 does not have to be provided.

In case of this embodiment, the vertical semiconductor apparatus 10E is formed so as to have a thickness of approximately 400 μm as a whole.

In the vertical semiconductor apparatus 10E having such a structure, for example, assuming that the withstand voltage of the MOSFET is 600 V, approximately 1.5×10¹⁴ cm⁻³ is desirable as the density of the n-type semiconductor substrate 11.

As the thickness D5 in FIG. 25, namely, the thickness D5 obtained by subtracting the thickness D2 of the p type base layer 12 and the thickness D3 of the n+ buffer layer 21 from the thickness D1 of the n− type semiconductor substrate 11, the thickness of approximately 55 μm is desirable. When the thickness D5 is set to a value lower than 55 μm, e.g., to 35 μm, the withstand voltage is insufficient. When the thickness D5 is set to a value larger than 55 μm, e.g., to 70 μm, the resistance between the source and the drain which is a so-called ON resistance becomes high, and the loss at the time of turn-off is increased. That is, in the punch-through type MOSFET, the optimum value of the thickness D5 exists in accordance with the necessary withstand voltage.

It is preferable to reduce the thickness D2 of the p type base layer 12 so as to be capable of maintaining the withstand voltage, and the thickness of approximately 4 μm is desirable for example. When the thickness D2 of the p type base layer 12 is to set to a large value, e.g., 10 μm, the loss in the ON state is increased.

It is preferable to reduce the thickness D3 of the n+ type buffer layer 21 so as to be capable of maintaining the withstand voltage, and the thickness of approximately 1 μm is desirable, for example. If the thickness D3 of the n+ type buffer layer 21 is set to a large value, e.g., 10 μm, the loss is not increased when the density of the n+ type buffer layer 21 is sufficiently high. However, if this thickness is small, the n+ type buffer layer 21 can be readily formed.

Based on this, in case of forming the punch-through type MOSFET having the planar gate structure whose withstand is 600 V, the thickness D1 of the n− type semiconductor substrate 11 is set to, e.g., 60 μm. As a result, there can be realized the MOSFET with less loss irrespective presence/absence of the joint substrate 22.

Here, in cases where a material of the n− type semiconductor substrate 11 is monocrystal silicon and the MOSFET whose withstand voltage is 600 V is created, as described above, when the thickness D1 of the n− type semiconductor substrate 11 is set to 60 μm, the MOSFET with small loss can be realized. However, when the thickness D1 of the n− type semiconductor substrate 11 is not more than 100 μm, the mechanical strength is insufficient. Therefore, it may be readily destroyed by an impact shock from the outside during or after manufacture. Thus, the joint substrate 22 is joined to the MOSFET and the thickness D6 of the joint substrate 22 is set to, e.g., approximately 340 μm (thickness not less than 200 μm). As a result, the cost can be reduced as compared with the case of forming the epitaxial layer, the sufficient mechanical strength can be obtained, and the MOSFET with small loss can be provided.

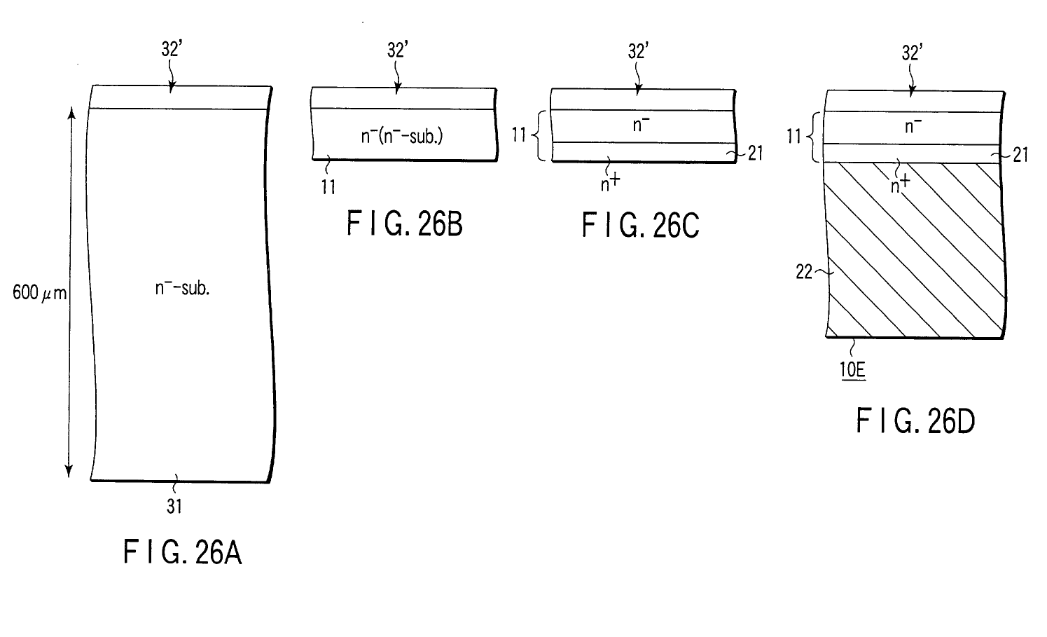

FIGS. 26A to 26D show a method for manufacturing the vertical semiconductor apparatus having the structure illustrated in FIG. 25. In case of manufacturing the vertical semiconductor apparatus 10E, as shown in FIG. 26A for example, an n− type wafer (first conductive type semiconductor substrate (n−-Sub.)) 31 having the thickness of approximately 600 μm is prepared. Then, an MOS structure 32′ having the planar gate structure is formed at the surface portion of the wafer 31. That is, a plurality of p type base layers 12 are first formed in the surface area of the n− type wafer 31 so as to have the thickness of approximately 4 μm through diffusion of impurities. Thereafter, a gate insulation film 15 and a gate electrode 16 are formed on the surface of the n− type wafer 31. Further, before and after formation of the gate electrode 16, a source electrode 14′ is formed on the surface of the n− type wafer 31. Furthermore, an n+ type source layer 13′ is formed in the surface area of the p type base layer 12 by diffusion of impurities with the gate electrode 16 and the source electrode 14′ being used as masks. In this manner, the MOS structure 32′ having the planar gate structure is formed at the surface portion of the n− type wafer 31.

Subsequently, as shown in FIG. 26B for example, a part of the surface of the n− type wafer 31 on which the MOS structure 32′ is not formed is removed by the polishing method or the like. As a result, the n− type semiconductor substrate 11 is formed. In this case, the thickness D1 of the n− type semiconductor substrate 11 excluding the gate electrode 16 and the source electrode 14′ is caused to be set to approximately 60 μm.

Then, as shown in FIG. 26C for example, an n+ type buffer layer 21 is formed on the surface of the n− type semiconductor substrate 11 on which the MOS structure 32′ is not formed. At this moment, the n+ buffer layer 21 is formed so as to have the thickness of approximately 1 μm by the ion implantation method.

In this manner, after forming the MOSFET, as shown in FIG. 26D for example, the joint substrate 22 having the thickness of approximately 340 μm is brought into contact with the surface of the n− type semiconductor substrate 11 on which the MOS structure 32′ is not formed. Then, the MOSFET and the joint substrate 22 are joined to each other by, e.g., heating.

Further, the substrate electrode 23 is formed on the non-joining surface of the joint substrate 22 with respect to the n− type semiconductor substrate 11 according to needs. Furthermore, the vertical semiconductor apparatus 10E having the structure illustrated in FIG. 25 is finally completed by separation/division in accordance with each MOSFET.

In this embodiment, when manufacturing the vertical semiconductor apparatus 10E, a wafer having the thickness of 600 μm is used. Therefore, the sufficient mechanical strength can be assured not only after completion of the vertical semiconductor apparatus 10E but warpage or an impact shock from the outside during manufacture.

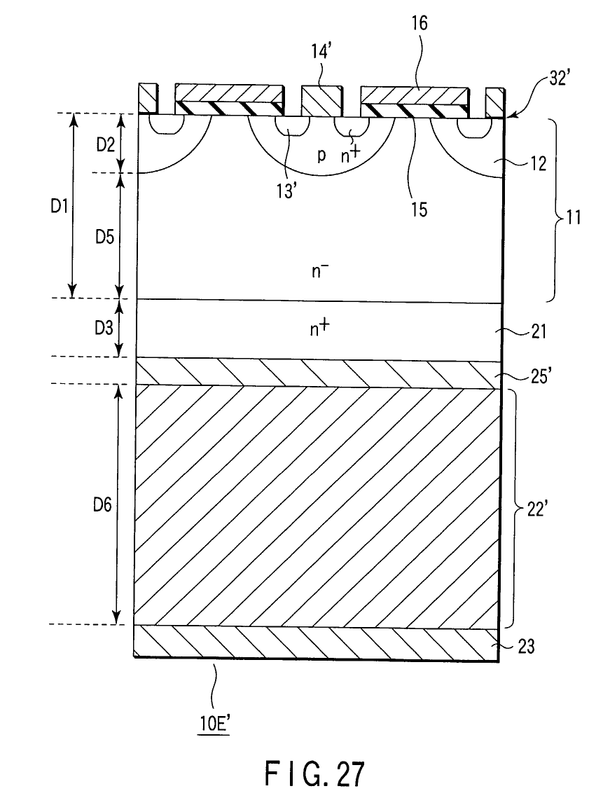

FIG. 27 shows an example (vertical semiconductor apparatus 10E′) where the semiconductor layer is used for the joint substrate in a vertical semiconductor apparatus 10E according to a fifth embodiment of the present invention.

In FIG. 27, a drain electrode (second electrode) 25′ is connected to the lower surface (back side) of the n− type semiconductor substrate 11 on which the MOS structure 32′ having the planar gate structure is formed. Moreover, the joint substrate 22′ is joined to the drain electrode 25′. In this case, as the joint substrate 22′, besides a metal such as Al, high-density p type or n type monocrystal silicon or polycrystal (poly-) silicon as a conductive material is used, for example. In particular, the joint substrate 22′ is configured not to partially have an impurity diffusion layer obtained through ion implantation or the like. In addition, as the drain electrode 25′, a metal such as Al or high-density polysilicon or amorphous silicon is used.

In the vertical semiconductor apparatus 10E′ with such a structure, the advantages substantially similar to those of the vertical semiconductor apparatus 10E illustrated in FIG. 25 can be obtained. In particular, when the drain electrode 25′ and the joint substrate 22′ are formed by using a material equal to that of the MOSFET (same element), namely, silicon, physical properties such as a thermal expansion coefficient of each part can be uniformized. As a result, deformation with respect to thermal stress can be suppressed. However, when the MOSFET is operated at a high speed, it is preferable to use a metal to the drain electrode 25′ and the joint substrate 22′.

(Sixth Embodiment)

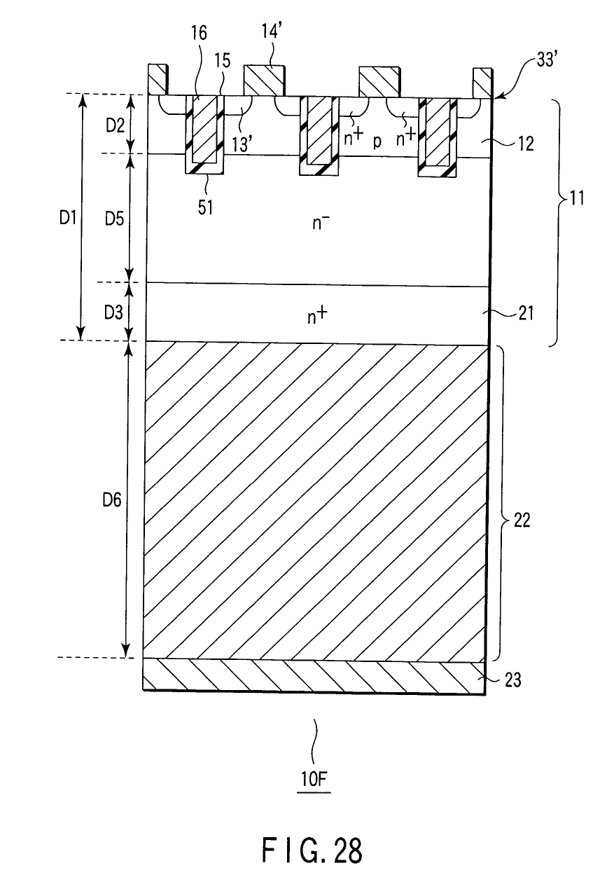

FIG. 28 shows a structural example of a vertical semiconductor apparatus 10F according to a sixth embodiment of the present invention. It is to be noted that description will be given as to an example where the embodiment of the present invention is applied to the punch-through type MOSFET having the trench gate structure.

In FIG. 28, a p type base layer 12 which is of the second conductive type is formed in the surface area of an n− type semiconductor substrate (for example, monocrystal silicon) 11 which is of the first conductive type. A plurality of n+ type source layers 13′ are formed in the surface area of the p type base layer 12. A plurality of source electrode 14′ are arranged on the surface of the n− type semiconductor substrate 11. Each source electrode 14′ is connected to the p type base layer 12 and the n+ type source layer 13′. Further, a plurality of trenches 51 are formed in the surface area of the p type base layer 12. Each trench 51 is formed so as to have a depth which pierces the n+ type source layer 13′ and the p type base layer 12 and reaches the n− type semiconductor substrate 11. A gate electrode 16 is embedded in each trench 51 with a gate insulation film 15 interposed therebetween. In this manner, an MOS (Metal Oxide Semiconductor) structure 33′ having a trench gate structure is formed at the surface portion of the n− type semiconductor substrate 11.

On the other hand, the n+ type buffer layer 21 is formed in the lower (back side) area of the n− type semiconductor substrate, namely, on the surface thereof where the MOS structure 33′ is not formed. As a result, there is realized the punch-through type MOSFET (semiconductor element) having a so-called trench gate structure which becomes conductive through movement of the carrier in the vertical direction of the n− type semiconductor substrate 11.

Furthermore, the joint substrate 22 is joined to the lower surface (back side) of the n− type semiconductor substrate 11. That is, the joint substrate 22 is provided to contact with the n+ type buffer layer 21. The joint substrate 22 is formed by using a metal (conductive material) such as aluminium (Al). Moreover, the substrate electrode (first electrode) 23 can be formed on the non-joining surface of the joint substrate 22 with respect to the n− type semiconductor substrate 11 according to needs. However, the substrate electrode 23 is formed by using nickel (Ni) or gold (Au) which is superior to the joint substrate 22 in the joint property with respect to solder when mounting the vertical semiconductor apparatus 10F. That is, when the joint substrate 22 is formed by using a metal with the excellent joint property with respect to solder, the substrate electrode 23 does not have to be provided.

In case of this embodiment, the vertical semiconductor apparatus 10F is formed so as to have a thickness of approximately 400 μm as a whole.

In the vertical semiconductor apparatus 10F having such a structure, when the thickness D1 of the n− type semiconductor substrate 11 is set to approximately 60 μm, the thickness D6 of the joint substrate 22 to be joined is set to, e.g., approximately 340 μm (thickness not less than 200 μm). By doing so, the cost can be reduced as compared with the case of forming the epitaxial layer, the sufficient mechanical strength can be obtained, and the MOSFET with small loss can be provided.

It is to be noted that the vertical semiconductor apparatus 10F can be formed by the process substantially similar to that illustrated in FIGS. 26A to 26D, for example.

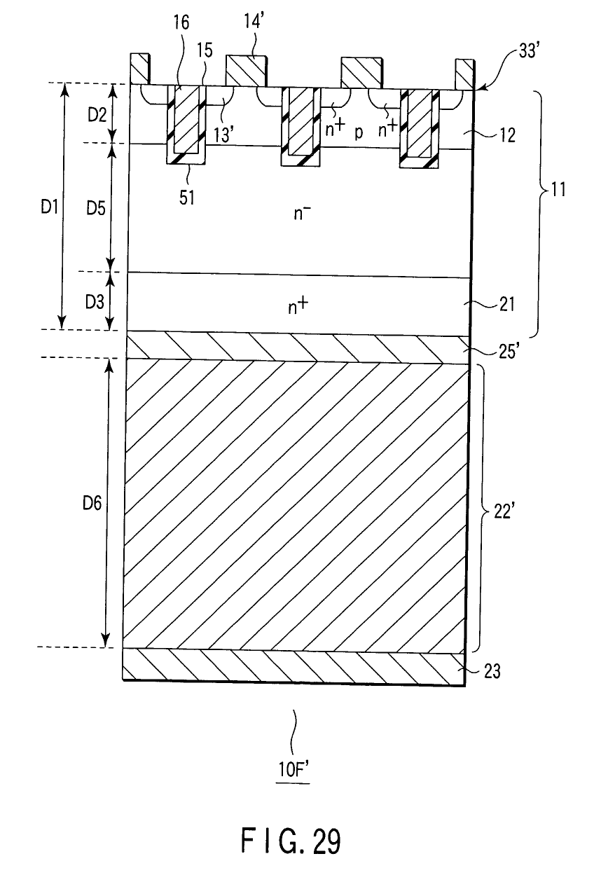

FIG. 29 shows an example (vertical semiconductor apparatus 10F′) where the semiconductor layer is used for the joint substrate in a vertical semiconductor apparatus 10F according to a sixth embodiment of the present invention.

In FIG. 29, the drain electrode (second electrode) 25′ is connected to the lower surface (back side) of the n− type semiconductor substrate 11 on which the MOS structure 33′ having the trench gate structure is formed. Furthermore, the joint substrate 22′ is joined to the drain electrode 25. In this case, as the joint substrate 22′, besides a metal such as Al, high-density p type or n type monocrystal silicon or polycrystal (poly-) silicon as a conductive material is used, for example. In particular, the joint substrate 22′ is configured not to partially have an impurity diffusion layer obtained though ion implantation or the like. Moreover, as the drain electrode 25′, a metal such as Al, high-density polysilicon or amorphous silicon is used, for example.

In the vertical semiconductor apparatus 10F′ having such a structure, the advantages substantially similar to those in the vertical semiconductor apparatus 10F illustrated in FIG. 28 can be obtained. In particular, when the drain electrode 25′ and the joint substrate 22′ are formed by using a material similar to that of the MOSFET (same element), namely, silicon, physical properties such as a thermal expansion coefficient of each part can be uniformized. As a result, deformation with respect to thermal stress or the like can be suppressed. However, when the MOSFET is operated at a high speed, it is preferable to use a metal for the drain electrode 25′ and the joint substrate 22′.

(Seventh Embodiment)

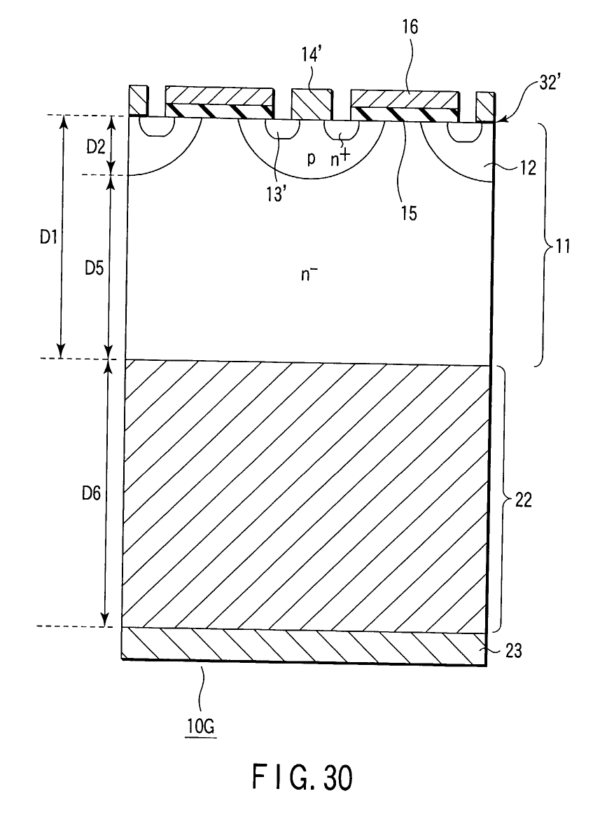

FIG. 30 shows a structural example of a vertical semiconductor apparatus 10G according to a seventh embodiment of the present invention. It is to be noted that description will be given as to an example in which the embodiment of the present invention is applied to a non-punch-through type MOSFET having a planar gate structure.

In FIG. 30, a plurality of p type base layers 12 which are of the second conductive type are formed in the surface area of the n− type semiconductor substrate (for example, monocrystal silicon) 11 which is of the first conductive type. A plurality of n+ type source layers 13′ are formed in the surface area of the p type base layer 12. A plurality of source electrodes 14′ are arranged on the surface of the n− type semiconductor substrate 11. Each source electrode 14′ is connected to the p type base layer 12 and the n+ type source layer 13′. In addition, a plurality of gate electrodes 16 are formed on the surface of the n− type semiconductor substrate 11 with the gate insulation film 15 interposed therebetween. Each gate electrode 16 is adjacent to the n− type semiconductor substrate 11, the p type base layer 12 and the n+ type source layer 13′. In this manner, an MOS (Metal Oxide Semiconductor) structure 32 having the planar gate structure is formed at the surface portion of the n− type semiconductor substrate 11. As a result, there is realized a non-punch-through type MOSFET (semiconductor element) having a so-called planar gate structure which becomes conductive through movement of the carrier in the vertical direction of the n− type semiconductor substrate 11.

In addition, a joint substrate 22 is joined to the lower surface (back side) of the n− type semiconductor substrate 11. That is, this joint substrate 22 is provided to contact with the n− type semiconductor substrate 11. The joint substrate 22 is formed of a metal (conductive material) such as aluminium (Al). Additionally, a substrate electrode (first electrode) 23 can be formed on the non-joining surface of this joint substrate 22 with respect to the n− type semiconductor substrate 11 according to needs. However, the substrate electrode 23 is formed of nickel (Ni) or gold (Au) which is superior to the joint substrate 22 in the joint property with respect to solder when mounting the vertical semiconductor apparatus 10G. That is, when the joint substrate 22 is formed of a metal with the excellent joint property with respect to solder, the substrate electrode 23 does not have to be provided.

In case of this embodiment, the vertical semiconductor apparatus 10G is formed so as to have the thickness of approximately 400 μm as a whole.

In the vertical semiconductor apparatus 10G having such a structure, assuming that the withstand voltage of the MOSFET is, e.g., 600 V, approximately 1.5×10¹⁴ cm⁻³ is desirable as the density of the n− type semiconductor substrate 11.

As the thickness D5 in FIG. 30, namely the thickness D5 obtained by subtracting the thickness D2 of the p type base layer 12 from the thickness D1 of the n− type semiconductor substrate 11, approximately 95 μm is desirable. When the thickness D5 is set to a value lower than 95 μm, e.g., 75 μm, the withstand voltage becomes insufficient. When the thickness D5 is set to a value larger than 95 μm, e.g., 120 μm, the resistance between the source and the drain, i.e., the ON resistance becomes high, and the loss at the time of turn-off is increased. That is, in the non-punch-through type MOSFET, the optimum value of the thickness D5 exists in accordance with the necessary withstand voltage.

It is preferable to reduce the thickness D2 of the p type base layer 12 so as to be capable of maintaining the withstand voltage, approximately 4 μm is desirable, for example. When the thickness D2 of the p type base layer 12 is increased to, e.g., 10 μm, the loss in the ON state is increased.

Based on this, when producing the non-punch-through type MOSFET having the planar gate structure whose withstand voltage is 600 V, the thickness D1 of the n− type semiconductor substrate 11 is set to, e.g., 99 μm. As a result, the MOSFET with small loss can be realized irrespective of presence/absence of the joint substrate 22.

Here, in cases where a material of the n− type semiconductor substrate 11 is monocrystal silicon and the MOSFET whose withstand voltage is 600 V is created, when the thickness D1 of the n− type semiconductor substrate 11 is set to 99 μm as described above, the MOSFET with small loss can be realized. However, when the thickness D1 of the n− type semiconductor substrate 11 is not more than 100 μm, the mechanical strength is insufficient. Therefore, the product may be readily destroyed from an impact shock from the outside during or after manufacture. Thus, the joint substrate 22 is joined to the MOSFET, and the thickness D6 of the joint substrate 22 is set to, e.g., approximately 301 μm (thickness not less than 200 μm). As a result, the cost can be reduced as compared with a case of forming the epitaxial layer, the sufficient mechanical strength can be obtained, and the MOSFET with small loss can be provided.

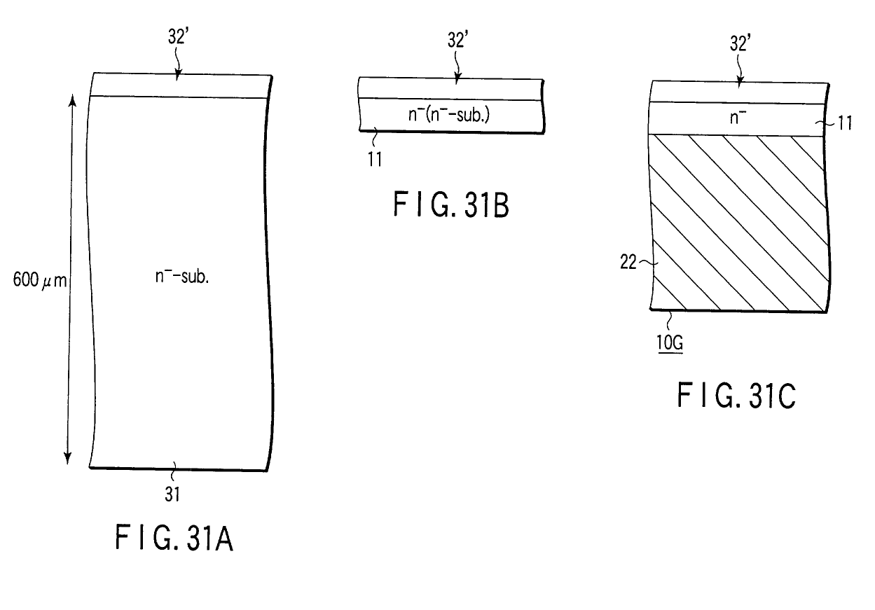

FIGS. 31A to 31C show a method for manufacturing the vertical semiconductor apparatus 10G having the structure illustrated in FIG. 30. In case of producing the vertical semiconductor apparatus 10G, as shown in FIG. 31A for example, an n− type wafer (first conductive type semiconductor substrate (n−-Sub.)) 31 having the thickness of approximately 600 μm is prepared. Further, the MOS structure 32′ having the planar gate structure is formed at the surface portion of the wafer 31. That is, a plurality of p type base layers 12 are first formed in the surface area of the n− type wafer 31 so as to have the thickness of approximately 4 μm by diffusion of impurities. Thereafter, the gate insulation film 15 and the gate electrode 16 are formed on the surface of the n− type wafer 31. Furthermore, before and after formation of the gate electrode 14′ is formed on the surface of the n− type wafer 31. Then, with the gate electrode 16 and the source electrode 14′ being used as masks, the n+ type source layer 13′ is formed in the surface area of the p type base layer 12 by diffusion of impurities. In this manner, the MOS structure 32′ having the planar gate structure is formed at the surface portion of the n− type wafer 31.

Subsequently, as shown in FIG. 31B for example, a part of the surface of the n− type wafer 31 on which the MOS structure 32′ is not formed is removed by the polishing method or the like. As a result, the n− type semiconductor substrate 11 is formed. In this case, the thickness D1 of the n− type semiconductor substrate 11 excluding the gate electrode 16 and the source electrode 14′ is set to approximately 99 μm.

In this manner, after forming the MOSFET, as shown in FIG. 31C for example, the joint substrate 22 having the thickness of 301 μm is brought into contact with the surface of the n− type semiconductor substrate 11 on which the MOS structure 32′ is not formed. Then, the MOSFET and the joint substrate 22 are joined to each other by, e.g., heating.

Moreover, the substrate electrode 23 is formed on the non-joining surface of the joint substrate 22 with respect to the n− type semiconductor substrate 11 according to needs. Then, the vertical semiconductor apparatus 10G having the structure illustrated in FIG. 30 is finally completed by separation/division in accordance with each MOSFET.

In this embodiment, when manufacturing the vertical semiconductor apparatus 10G, a wafer having the thickness of approximately 600 μm is used. Therefore, the sufficient mechanical strength can be assured not only after completion of the vertical semiconductor apparatus 10G but with respect to warpage or an impact shock from the outside during manufacture.

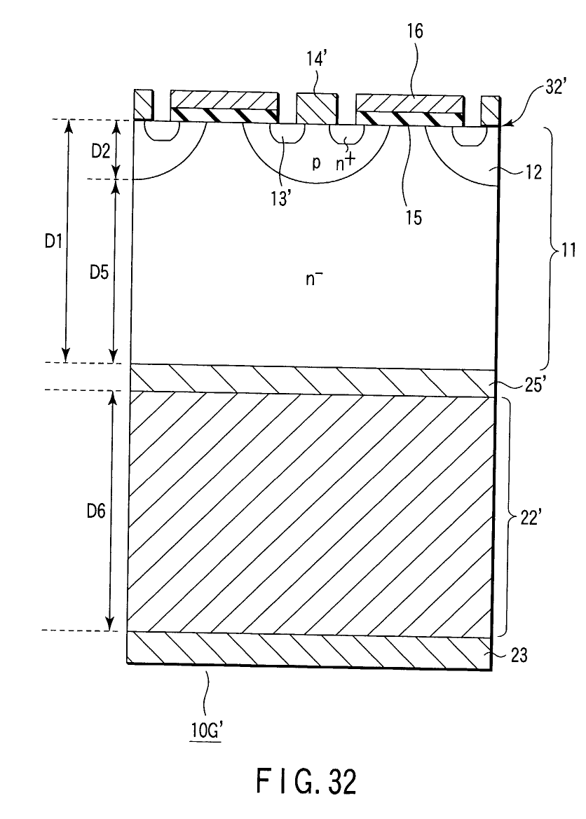

FIG. 32 shows an example (vertical semiconductor apparatus 10G′) where the semiconductor layer is used for the joint substrate in the vertical semiconductor apparatus 10G according to the seventh embodiment of the present invention.

In FIG. 32, a drain electrode (second electrode) 25′ is connected to the lower surface (back side) of an n− type semiconductor substrate 11 to which the MOS structure 32′ having the planar gate structure is formed. Also, the joint substrate 22′ is joined to the drain electrode 25′. In this case, as the joint substrate 22′, beside a metal such as Al, high-density p type or n type monocrystal silicon or polycrystal (poly-) silicon as a conductive material is used, for example. In particular, the joint substrate 22′ is configured not to partially have an impurity diffusion layer obtained through ion implantation. Further, as the drain electrode 25′, a metal such as Al, high-density polysilicon or amorphous silicon is used.

In the vertical semiconductor apparatus 10G′ having such a structure, the advantages substantially similar to those of the vertical semiconductor apparatus 10G illustrated in FIG. 30 can be obtained. In particular, when the drain electrode 25′ and the joint substrate 22′ are formed by using a material equal to that of the MOSFET (same element), namely, silicon, physical properties such as a thermal expansion coefficient of each part can be uniformized. As a result, deformation with respect to thermal stress can be also suppressed. However, when the MOSFET is operated at a high speed, it is preferable to use a metal to the drain electrode 25′ and the joint substrate 22′.

(Eighth Embodiment)

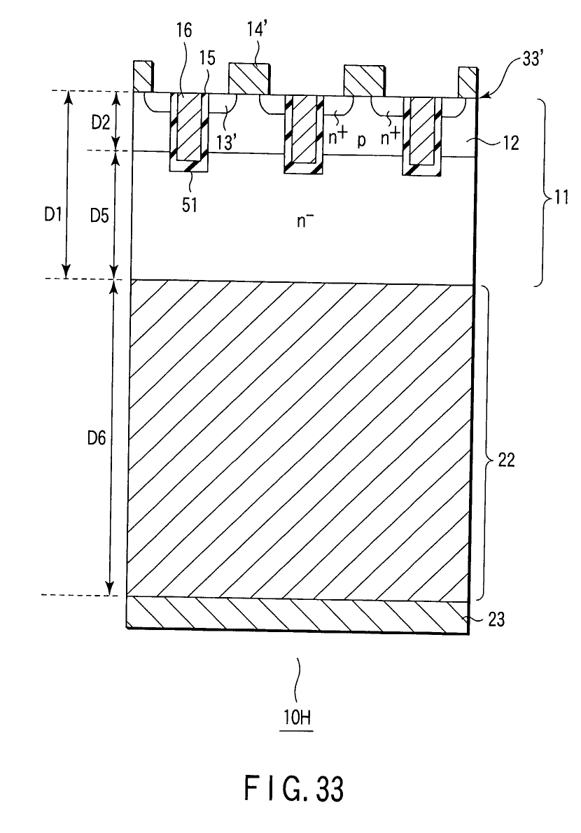

FIG. 33 shows a structural example of a vertical semiconductor apparatus 10H according to an eighth embodiment of the present invention. It is to be noted that description will be given as to an example where a non-punch-through type MOSFET having the trench gate structure.

In FIG. 33, a p type base layer 12 which is of the second conductive type is formed in the surface area of the n− type semiconductor substrate (for example, monocrystal silicon) 11 which is of the first conductive type. A plurality of n+ type source layers 13′ are formed in the surface area of the p type base layer 12. A plurality of source electrodes 14′ are arranged on the surface of the n− type semiconductor substrate 11. Each source electrode 14′ is connected to the p type base layer 12 and the n+ type source layer 13′. Furthermore, a plurality of trenches 51 are formed in the surface area of the p type base layer 12. Each trench 51 is formed so as to have the depth which pierces the n+ type source layer 13′ and the p type base layer 12 and reaches the n− type semiconductor substrate 11. A gate electrode 16 is embedded in each trench 51 with a gate insulation film 15 interposed therebetween. In this manner, an MOS (Metal Oxide Semiconductor) structure 33′ having the trench gate structure is formed at the surface portion of the n− type semiconductor substrate 11. In this manner, there is realized a non-punch-through type MOSFET (semiconductor element) having a so-called trench gate structure is realized which becomes conductive through movement of the carrier in the vertical direction of the n− type semiconductor substrate 11.

Furthermore, the joint substrate 22 is joined to the lower surface (back side) of the n− type semiconductor substrate 11. That is, the joint substrate 22 is provided to contact with the n− type semiconductor substrate 11. The joint substrate 22 is formed by using a metal (conductive material) such as aluminium (Al). Then, a substrate electrode (first electrode) 23 can be formed on the non-joining surface of the joint substrate 22 with respect to the n− type semiconductor substrate 11. However, the substrate electrode 23 is formed of, e.g., nickel (Ni) or gold (Au) which is superior to the joint substrate 22 in the joint property with respect to solder when mounting the vertical semiconductor apparatus 10H. That is, when the joint substrate 22 is formed by using a metal with the excellent joint property with respect to solder, the substrate electrode 23 does not have to be provided.

In case of this embodiment, the vertical semiconductor apparatus 10H is formed so as to have the thickness of approximately 400 μm as a whole.

In the vertical semiconductor apparatus 10H having such a structure, when the thickness D1 of the n− type semiconductor substrate 11 is set to, e.g., 99 μm, the thickness D6 of the joint substrate 22 to be joined is set to, e.g., approximately 301 μm (thickness of not less than 200 μm). By doing so, the cost can be reduced as compared with the case of forming the epitaxial layer, the sufficient mechanical strength can be obtained, and the MOSFET with small loss can be provided.

It is to be noted that the vertical semiconductor apparatus 10H can be formed by the process substantially similar to that illustrated in FIGS. 31A to 31C, for example.

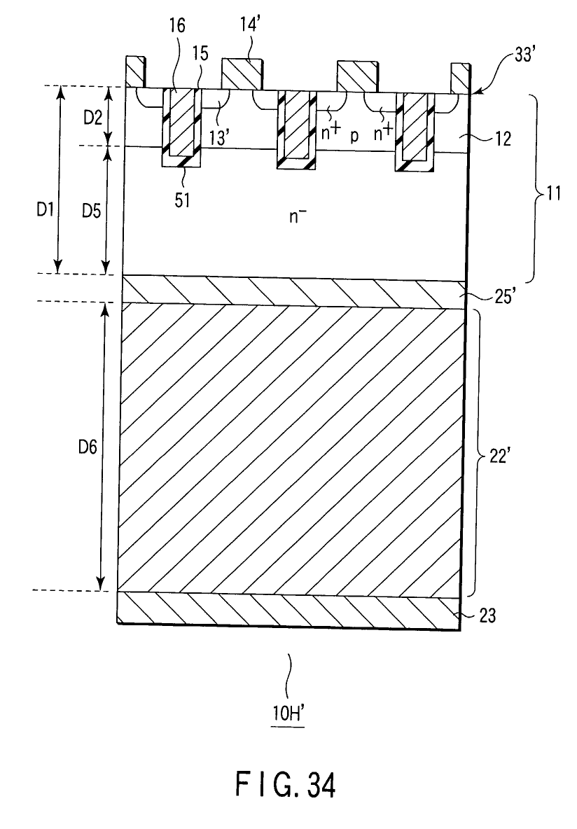

FIG. 34 shows an example (vertical semiconductor apparatus 10H′) where the semiconductor layer is used for the joint substrate in the vertical semiconductor apparatus 10H according to the eighth embodiment of the present invention.

In FIG. 34, a drain electrode (second electrode) 25′ is connected to the lower surface (back side) of the n− type semiconductor substrate 11 to which the MOS structure 33′ having the trench gate structure is formed. Moreover, the joint substrate 22′ is joined to the drain electrode 25′. In this case, as the joint substrate 22′, besides a metal such as Al, high-density p type or n type monocrystal silicon or polycrystal (poly-) silicon as a conductive material is used, for example. In particular, the joint substrate 22′ is configured not to partially have an impurity diffusion layer obtained through ion implantation or the like. Further, as the drain electrode 25′, a metal such as Al, high-density polysilicon or amorphous silicon is used, for example.

In the vertical semiconductor apparatus 10H having such a structure, the advantages substantially similar to those of the vertical semiconductor apparatus 10H illustrated in FIG. 33 can be obtained. In particular, when the drain electrode 25′ and the joint substrate 22′ are formed by using a material equal to that of the MOSFET (same element), namely, silicon, physical properties such as a thermal expansion coefficient of each part can be uniformized. As a result, deformation with respect to thermal stress can be suppressed. However, when the MOSFET is operated at a high speed, it is preferable to use a metal to the drain electrode 25′ and the joint substrate 22′.

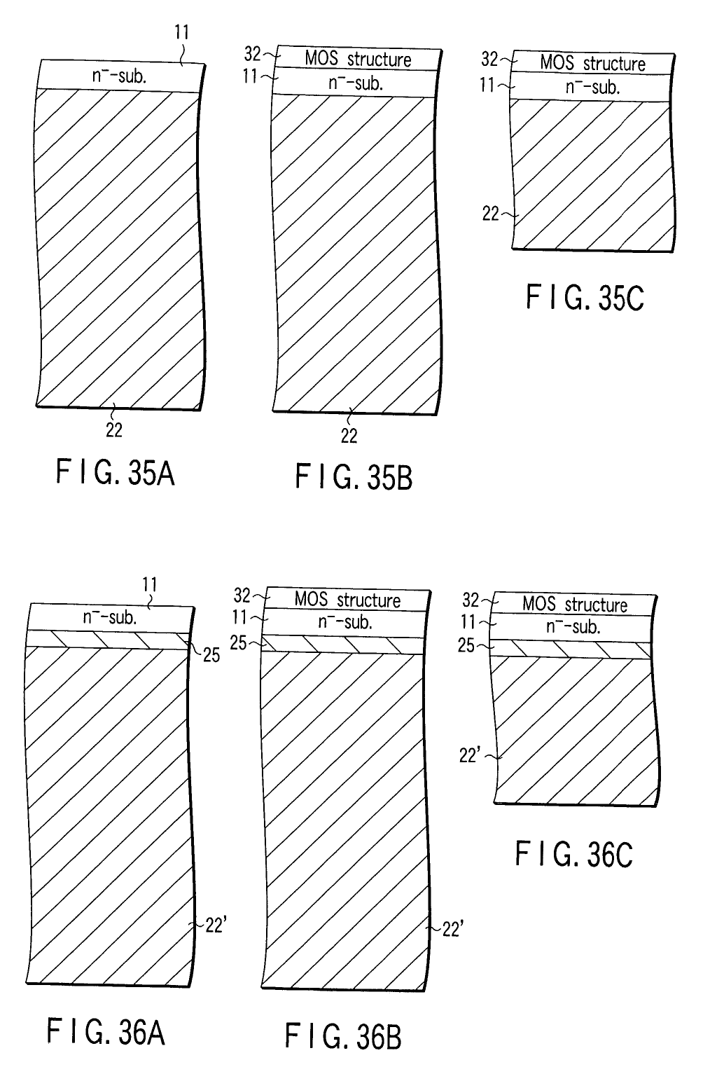

Incidentally, in each of the foregoing embodiments, as the method for manufacturing the vertical semiconductor apparatus, description has been given as to the case where the joint substrate is joined to the IGBT or the MOSFET directly or through the electrode. The embodiment of the present invention is not restricted thereto and, as shown in FIGS. 35A to 35C and FIGS. 36A to 36C for example, the MOS structure can be formed after joining the joint substrate.

(Ninth Embodiment)

FIGS. 35A to 35C show a method for manufacturing the vertical semiconductor apparatus according to a ninth embodiment of the present invention. Here, description will be given taking the vertical semiconductor apparatus (punch-through type IGBT having the planar gate structure) 10A illustrated in FIG. 1.

For example, when manufacturing the vertical semiconductor apparatus 10A, as shown in FIG. 35A, the joint substrate 22 having the thickness of approximately 600 μm is brought into contact with the non-joining surface of the n− type semiconductor substrate 11 having the thickness of 60 μm with respect to the MOS structure 32. Then, the n− type semiconductor substrate 11 and the joint substrate 22 are joined to each other by, e.g., heating.

Thereafter, as shown in FIG. 35B for example, the MOS structure 32 is formed in the surface area of the n− type semiconductor substrate 11, thereby forming the punch-through type IGBT having the planar gate structure.

In this manner, after forming the IGBT, as shown in FIG. 35C for example, a part of the non-joining surface of the joint substrate 22 with respect to the n− type semiconductor substrate 11 is removed by the polishing method or the like. As a result, the joint substrate 22 having the thickness of 340 μm is formed.

Thereafter, the substrate electrode 23 is formed on the non-joining surface of the joint substrate 22 with respect to the n− type semiconductor substrate 11 according to needs. Then, the vertical semiconductor apparatus 10A having the structure illustrated in FIG. 1 is finally completed by separation/division in accordance with each IGBT.

(10th Embodiment)

FIGS. 36A to 36C show a method for manufacturing a vertical semiconductor apparatus according to a 10th embodiment of the present invention. Here, description will be given as to the example of the vertical semiconductor apparatus (punch-through type IGBT having the planar gate structure) 10A′ illustrated in FIG. 11.

For example, when manufacturing the vertical semiconductor apparatus 10A′, as shown in FIG. 36A, the joint substrate 22′ having the thickness of 600 μm is brought into contact with the surface of the n− type semiconductor substrate 11 having the thickness of 60 μm, where the MOS structure 32 is not formed, through the collector electrode 25. Moreover, the collector electrode 25 and the joint substrate 22′ are joined to each other by, e.g., heating.

Thereafter, as shown in FIG. 36B for example, the punch-through type IGBT having the planar gate structure is formed by producing the MOS structure 32 in the surface area of the n− type semiconductor substrate 11.

In this manner, after forming the IGBT, as shown in FIG. 36C for example, a part of the non-joining surface of the joint substrate 22′ with respect to the collector electrode 25 is removed by the polishing method. As a result, the joint substrate 22′ having the thickness of 340 μm is formed.

Thereafter, the substrate electrode 23 is formed on the non-joining surface of the joint substrate 22′ with respect to the collector electrode 25 according to needs. Then, the vertical semiconductor apparatus 10A′ having the structure illustrated in FIG. 11 is finally completed by separation/division in accordance with each IGBT.

(11th Embodiment)

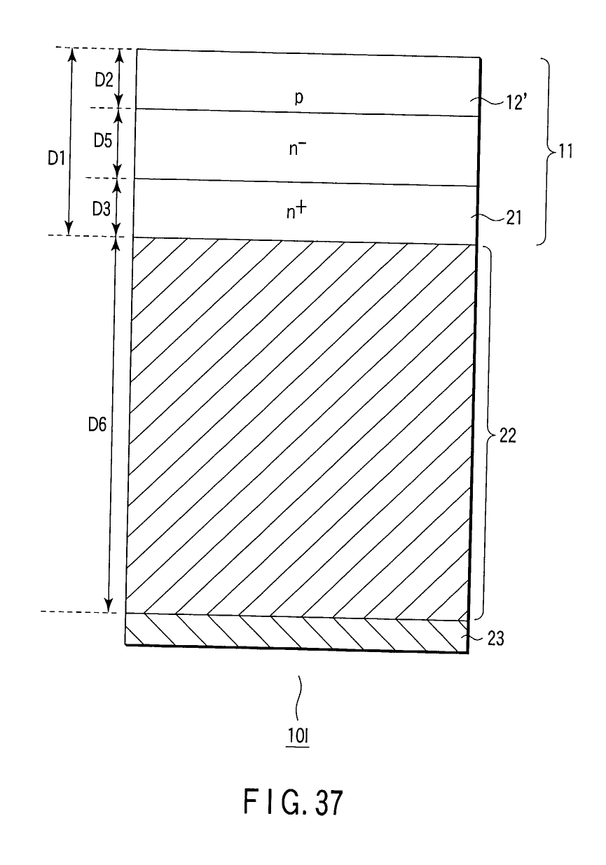

FIG. 37 shows a structural example of a vertical semiconductor apparatus 10I according to an 11th embodiment of the present invention. Incidentally, here, description will be given as to the case where the embodiment of the present invention is applied to a punch-through type diode.

In FIG. 37, a p type semiconductor layer 12′ which is of the second conductive type is formed in the surface area of an n− type semiconductor substrate (for example, monocrystal silicon) 11 which is of the first conductive type. On the other hand, an n+ type buffer layer 21 is formed on the lower (back side) area of the n− type semiconductor substrate 11, namely, the surface thereof where the p type semiconductor layer 12′ is not formed. As a result, there is realized a so-called punch-through type diode (semiconductor element) which becomes conductive through movement of the carrier in the vertical direction of the n− type semiconductor substrate 11.

In addition, the joint substrate 22 is joined to the lower surface (back side) of the n− type semiconductor substrate 11. That is, this joint substrate 22 is provided to contact with the n+ type buffer layer 21. The joint substrate 22 is formed by using a metal (conductive material) such as aluminium (Al). Further, the substrate electrode (first electrode) 23 can be formed on the non-joining surface of the joint substrate 22 with respect to the n− type semiconductor substrate 11 according to needs. However, the substrate electrode 23 is formed by using, e.g., nickel (Ni) or gold (Au) which is superior to the joint substrate in the joint property with respect to solder when mounting the vertical semiconductor apparatus 10I. That is, when the joint substrate 22 is formed by using a metal with the excellent joint property with respect to solder, the substrate electrode 23 does not have to be provided.

In case of this embodiment, the vertical semiconductor apparatus 10I is formed so as to have the thickness of approximately 400 μm as a whole.

In the vertical semiconductor apparatus 10I having such a structure, assuming that the withstand voltage of the diode is, e.g., 600 V, approximately 1.5×10¹⁴ cm⁻³ is desirable as the density of the n-type semiconductor substrate 11.

As the thickness D5 in FIG. 37, namely, the thickness D5 obtained by subtracting the thickness D2 of the p type semiconductor layer 12′ and the thickness D3 of the n+ type buffer layer 21 from the thickness D1 of the n− type semiconductor substrate 11, approximately 55 μm is desirable. When the thickness D5 is set to a value smaller than 55 μm, e.g., 35 μm, the withstand voltage becomes insufficient. When the thickness D5 is set to a value larger than 55 μm, e.g., 70 μm, the resistance between the anode and the cathode, i.e., a so-called ON resistance becomes high, and the loss at the time of turn-off is increased. That is, in the punch-through type diode, the optimum value of the thickness D5 exists in accordance with the necessary withstand voltage.

It is preferable to reduce the thickness D2 of the p type semiconductor layer 12′ so as to be capable of maintaining the withstand voltage, and the thickness of, e.g., 4 μm is desirable. When the thickness D2 of the p type semiconductor layer 12′ is set to a large value, e.g., 10 μm, the loss in the ON state is increased.

It is preferable to reduce the thickness D3 of the n+ type buffer layer 21 so as to be capable of maintaining the withstand voltage, and the thickness of, e.g., 1 μm is desirable. Even if the thickness D3 of the n+ type buffer layer 21 is set to a large value, e.g., 10 μm, the loss is not increased when the density of the n+ type buffer layer 21 is sufficiently high. However, when the thickness is small, the n+ type buffer layer 21 can be readily formed.

Based on this, in case of producing the punch-through type diode whose withstand voltage is 600 V, the thickness D1 of the n− type semiconductor substrate 11 is set to, e.g., 60 μm. As a result, the diode with small loss can be realized irrespective of presence/absence of the joint substrate 22.

Here, in cases where a material of the n− type semiconductor substrate 11 is monocrystal silicon and the diode whose withstand voltage is 600 V is created, when the thickness D1 of the n− type semiconductor substrate 11 is set to 60 μm as described above, the diode with small loss can be realized. However, when the thickness D1 of the n− type semiconductor substrate 11 is not more than 100 μm the mechanical strength is insufficient. Therefore, the semiconductor substrate may be readily destroyed by an impact shock from the outside during or after manufacture. Thus, the joint substrate 22 is joined to the diode and the thickness D6 of the joint substrate is set to approximately 340 μm (not less than 200 μm). As a result, the cost can be reduced as compared with the case of forming the epitaxial layer, the sufficient mechanical strength can be obtained, and the diode with small loss can be provided.

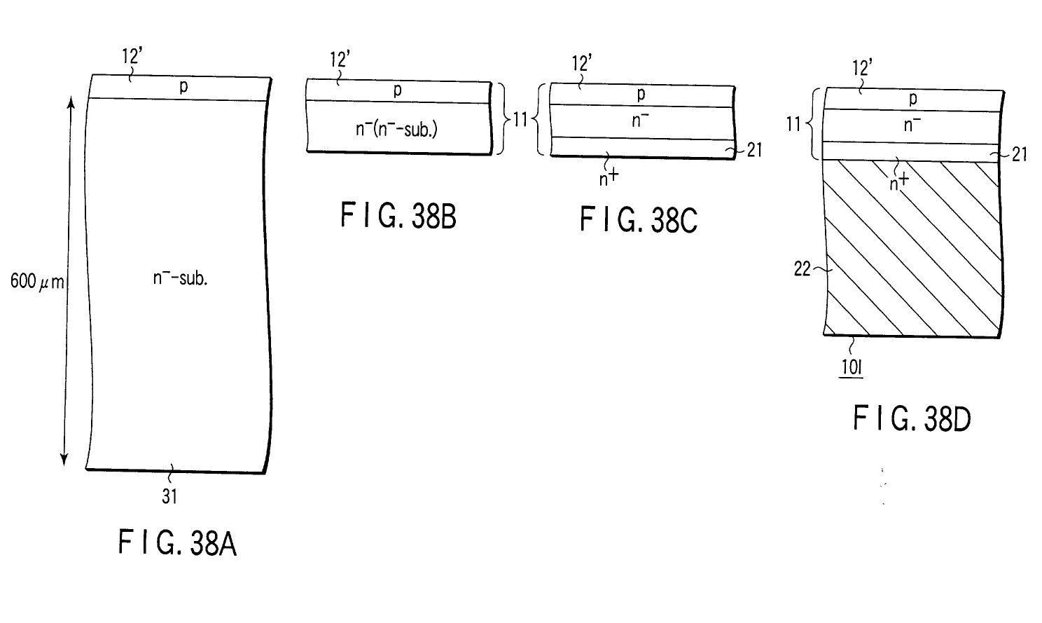

FIGS. 38A to 38D show a method for manufacturing the vertical semiconductor apparatus 10I illustrated in FIG. 37. In case of producing the vertical semiconductor apparatus 10I, as shown in FIG. 38A for example, an n− type wafer (first conductive type semiconductor substrate (n−-Sub.)) 31 having the thickness of approximately 600 μm is prepared. Then, a p type semiconductor layer 12′ is first formed in the surface area of the wafer 31 so as to have the thickness of approximately 4 μm through diffusion of impurities.

Subsequently, as shown in FIG. 38B for example, a part of the surface of the n− type wafer 31 on which the p type semiconductor layer 12′ is not formed is removed by the polishing method or the like. As a result, the n− type semiconductor substrate 11 is formed. In this case, the thickness D1 of the n− type semiconductor substrate 11 including the p type semiconductor layer 12′ is caused to be approximately 60 μm.

Then, as shown in FIG. 38C for example, an n+ type buffer layer 21 is formed on the surface of the n− type semiconductor substrate 11, on which the p type semiconductor layer 12′ is not formed, so as have the thickness of approximately 1 μm by the ion implantation method.

In this manner, after forming the diode, as shown in FIG. 38D for example, the joint substrate 22 having the thickness of approximately 340 μm is brought into contact with the n+ type buffer layer 21. Then, the diode and the joint substrate 22 are joined to each other by, e.g., heating.

Further, the substrate electrode 23 is formed on the non-joining surface of the joint substrate 22 with respect to the n+ type buffer layer 21 according to needs. Then, the vertical semiconductor apparatus 10I having the structure illustrated in FIG. 37 is finally completed by separation/division in accordance with each diode.

In this embodiment, when manufacturing the vertical semiconductor apparatus 10I, the wafer having the thickness of approximately 600 μm is used. As a result, the sufficient mechanical strength can be assured not only after completion of the vertical semiconductor apparatus 101 but with respect to warpage or an impact shock from the outside during manufacture.

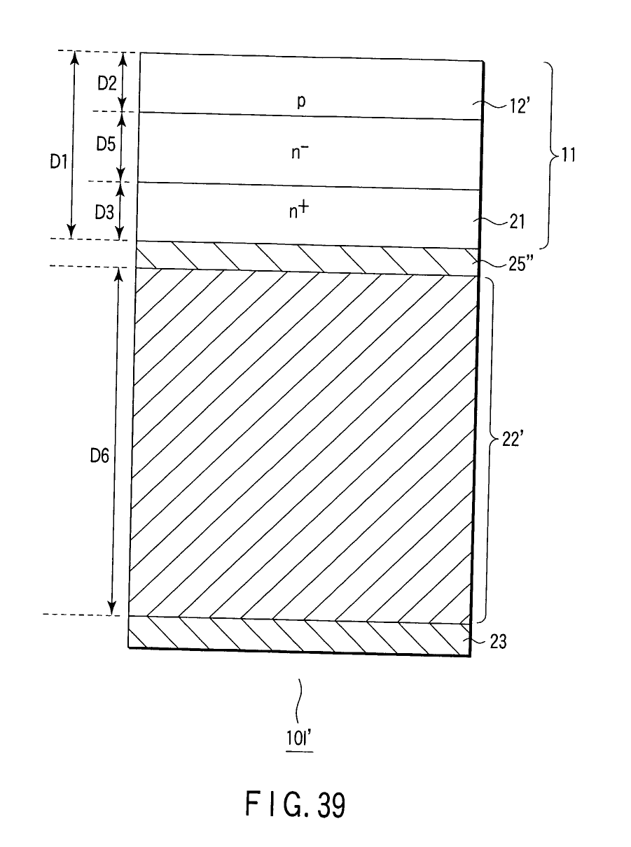

FIG. 39 shows an example (vertical semiconductor apparatus 10I′) where the semiconductor layer is used for the joint substrate in the vertical semiconductor apparatus 10I according to the 11th embodiment of the present invention.

In FIG. 39, an electrode (second electrode) 25″ is connected to the lower surface (back side) of the n-type semiconductor substrate 11 on which the n+ type buffer layer 21 is formed. Moreover, the joint substrate 22′ is joined to the electrode 25″. In this case, as the joint substrate 22′, besides a metal such as Al, high-density p type or n type monocrystal silicon or polycrystal (poly-) silicon as a conductive material is used, for example. In particular, the joint substrate 22′ is configured not to partially have an impurity diffusion layer obtained by ion implantation or the like. In addition, as the electrode 25″, a metal such as Al, or high-density polysilicon or amorphous silicon is used, for example.

In the vertical semiconductor substrate 10I′ having such a structure, the advantages substantially similar to those of the vertical semiconductor apparatus 10I illustrated in FIG. 37 can be likewise obtained. In particular, when the electrode 25″ and the joint substrate 22′ are formed by using a material equal to that of the diode (same element), namely, silicon, physical properties such as a thermal expansion coefficient of each part can be uniformized. As a result, deformation with respect to thermal stress can be suppressed. However, when the diode is operated at a high speed, it is preferable to use a metal to the electrode 25″ and the joint substrate 22′.

(12th Embodiment)

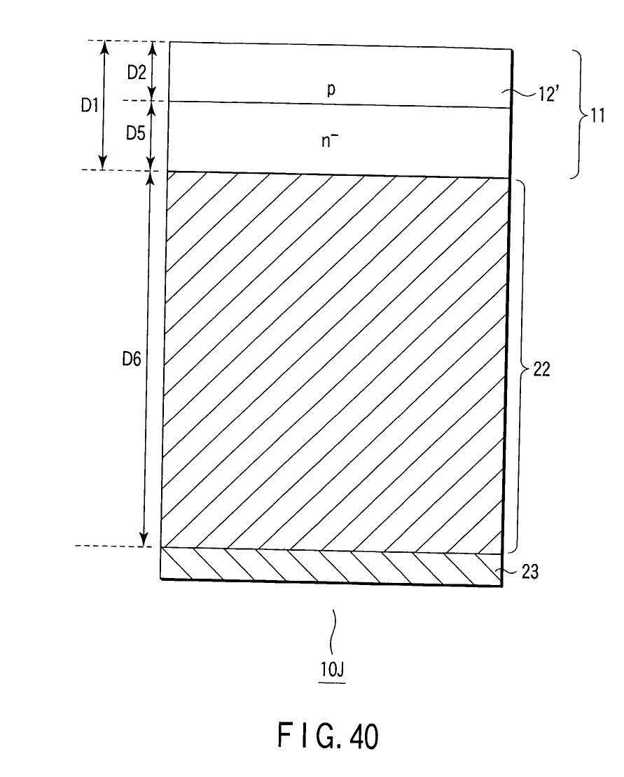

FIG. 40 shows a structural example of a vertical semiconductor apparatus 10J according to a 12th embodiment of the present invention. It is to be noted that description will be given as to an example where the embodiment of the present invention is applied to the non-punch-through type diode.

In FIG. 40, a p type semiconductor layer 12′ which is of the second conductive type is formed in the surface area of an n− type semiconductor substrate (for example, monocrystal silicon) 11 which is of the first conductive type. As a result, there is realized a so-called non-punch-through type diode (semiconductor element) which becomes conductive by movement of the carrier in the vertical direction of the n− type semiconductor substrate 11.

Moreover, the joint substrate 22 is joined to the lower surface (back side) of the n− type semiconductor substrate 11. That is, this joint substrate 22 is provided to contact with the n− type semiconductor substrate 11. The joint substrate 22 is formed by using a metal (conductive material) such as aluminium (Al). Further, a substrate electrode (first electrode) 23 can be formed to the non-joining surface of the joint substrate 22 with respect to the n− type semiconductor substrate 11. However, the substrate electrode (second electrode) 23 is formed by using nickel (Ni) or gold (Au) which is superior to the joint substrate in the joint property with respect to solder when mounting the vertical semiconductor apparatus 10J. That is, when the joint substrate 22 is formed by using a metal with the excellent property with respect to solder, the substrate electrode 23 does not have to be provided.

In case of this embodiment, the vertical semiconductor apparatus 10J is formed so as to have the thickness of approximately 400 μm as a whole, for example.

In the vertical semiconductor apparatus 10J having such a structure, even when the thickness D1 of the n− type semiconductor substrate 11 is set to, e.g., 99 μm, the thickness D6 of the joint substrate 22 to be joined is determined as, e.g., approximately 301 μm (thickness of not less than 200 μm). By doing so, the cost can be reduced as compared with the case of forming the epitaxial layer, the sufficient mechanical strength can be obtained, and the diode with small loss can be provided.

It is to be noted that the vertical semiconductor apparatus 10J can be formed by the process substantially similar to that illustrated in, e.g., FIGS. 38A to 38D.

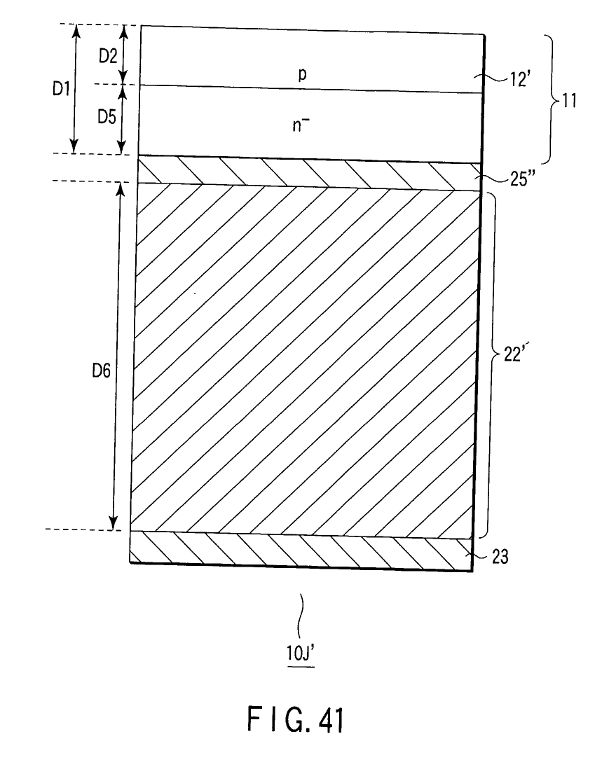

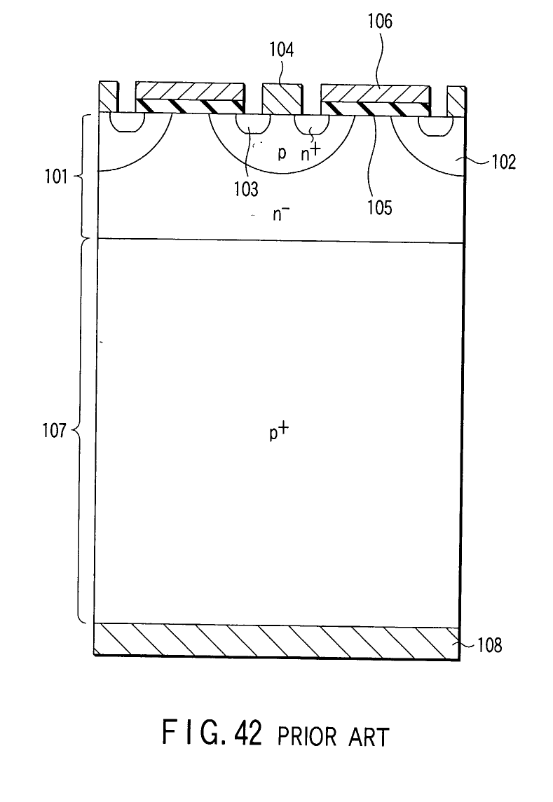

FIG. 41 shows an example (vertical semiconductor apparatus 10J′) where the semiconductor layer is used for the joint substrate in the vertical semiconductor apparatus 10J according to the 12th embodiment of the present invention.

In FIG. 41, the electrode (second electrode) 25″ is connected to the lower surface (back side) of the n− type semiconductor substrate to which the p type semiconductor layer 12′ is formed. Moreover, the joint substrate 22′ is joined to the electrode 25″. In this case, as the joint substrate 22′, beside a metal such as Al, high-density p type or n type monocrystal silicon or polycrystal (poly-) silicon as a conductive material is used. In particular, the joint substrate 22′ is configured not to partially have an impurity diffusion layer obtained through ion implantation or the like. In addition, as the electrode 25″, for example, a metal such as Al, or high-density polysilicon or amorphous silicon is used.

In the vertical semiconductor apparatus 10J′ having such a structure, the advantages substantially similar to that of the vertical semiconductor apparatus 10J illustrated in FIG. 40 can be obtained. In particular, when the electrode 25″ and the joint substrate 22′ are formed by using a material equal to that of the diode (same element), namely, silicon, physical properties such as a thermal expansion coefficient of each part can be uniformized. As a result, deformation with respect to thermal stress can be suppressed. However, when the diode is operated at a high speed, it is preferable to use a metal to the electrode 25″ and the joint substrate 22′.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

What is claimed is:

1. A semiconductor apparatus comprising:
a semiconductor element having a structure which becomes conductive by movement of a carrier in the vertical direction of a semiconductor substrate; and
a joint substrate joined to said semiconductor substrate in order to give mechanical strength to said semiconductor element.

2. The semiconductor apparatus according to claim 1, wherein said joint substrate is directly joined to said semiconductor substrate.

3. The semiconductor apparatus according to claim 2, wherein said joint substrate includes a conductive material.

4. The semiconductor apparatus according to claim 3, wherein said conductive material is a metal.

5. The semiconductor apparatus according to claim 1, wherein a first electrode is provided to a non-joining surface of said joint substrate.

6. The semiconductor apparatus according to claim 1, wherein said joint substrate is joined to said semiconductor substrate through a second electrode.

7. The semiconductor apparatus according to claim 6, wherein said joint substrate includes a conductive material.

8. The semiconductor apparatus according to claim 7, wherein said conductive material is a metal.

9. The semiconductor apparatus according to claim 7, wherein said conductive material is silicon.

10. The semiconductor apparatus according to claim 9, wherein said silicon includes a structure which does not partially have an impurity diffusion layer.

11. The semiconductor apparatus according to claim 6, wherein said second electrode is a metal.

12. The semiconductor apparatus according to claim 6, wherein said second electrode is silicon.

13. The semiconductor apparatus according to claim 1, wherein said semiconductor element has a thickness of not more than 100 μm.

14. The semiconductor apparatus according to claim 13, wherein said semiconductor element is a diode.

15. The semiconductor apparatus according to claim 1, wherein said joint substrate has a thickness of not less than 200 μm.

16. A semiconductor apparatus comprising:
a first main electrode;
a joint substrate formed on said first main electrode;
a semiconductor layer formed on said joint substrate;
a base layer formed in a main surface of said semiconductor layer;
an impurity diffusion layer formed in said base layer;
a second main electrode connected to said impurity diffusion layer and said base layer; and
a gate electrode formed over a portion between said semiconductor layer and said diffusion layer via an insulation film.

17. The semiconductor apparatus according to claim 16, wherein said joint substrate is a metal.

18. The semiconductor apparatus according to claim 16, wherein said joint substrate is silicon and said silicon includes a structure which does not partially have an impurity diffusion layer.

19. The semiconductor apparatus according to claim 16, wherein said semiconductor layer has a thickness of not more than 100 μm.

20. A semiconductor apparatus comprising:
a first main electrode;
a semiconductor layer formed on said first main electrode;
a base layer formed in a main surface of said semiconductor layer;
an impurity diffusion layer formed in said base layer;
a second main electrode connected to said impurity diffusion layer and said base layer;
a gate electrode formed over a portion between said semiconductor layer and said diffusion layer via an insulation film; and
a joint substrate joined to a lower surface of said first main electrode.

21. The semiconductor apparatus according to claim 20, wherein said joint substrate includes a conductive material.

22. The semiconductor apparatus according to claim 21, wherein said conductive material is a metal.

23. The semiconductor apparatus according to claim 21, wherein said conductive material is silicon.

24. The semiconductor apparatus according to claim 23, wherein said silicon includes a structure which does not partially have an impurity diffusion layer.

25. The semiconductor apparatus according to claim 20, wherein said second main electrode is a metal.

26. The semiconductor apparatus according to claim 25, wherein said second main electrode is silicon.

27. The semiconductor apparatus according to claim 20, wherein said semiconductor layer has a thickness of not more than 100 μm.
